(19) United States
(12) Patent Application Publication
(10) Pub. No.: US 2009/0017292 A1
(43) Pub. Date: Jan. 15, 2009

(54) Reactive flow deposition and synthesis of inorganic foils

(76) Inventors: Henry Hieslmair, San Francisco, CA (US); Ronald J. Mosso, Fremont, CA (US); Narayan Solayappan, Nanjundapuram (IN); Shivkumar Chiruvolu, San Jose, CA (US); Julio E. Morris, Fremont, CA (US)

Correspondence Address: DARDI & ASSOCIATES, PLLC, 220 S. 6TH ST., SUITE 2000, U.S. BANK PLAZA, MINNEAPOLIS, MN, 55402, US

(21) Appl. No.: 12/157,713

(22) Filed: Jun. 12, 2008

Related U.S. Application Data
(60) Provisional application No. 60/934,793, filed on Jun. 15, 2007.
(60) Provisional application No. 61/062,398, filed on Jan. 25, 2008.

(51) Int. Cl. B32B 5/00; C23C 16/00; C23C 16/513; B05D 1/00; B01J 19/12; B05D 1/36; C23C 16/44

(52) U.S. Cl. 428/336; 427/248.1; 427/578; 427/585; 427/255.5; 428/334; 428/335; 428/332; 427/203; 427/184; 427/595

(57) ABSTRACT

Sub-atmospheric pressure chemical vapor deposition is described with a directed reactant flow and a substrate that moves relative to the flow. Thus, using this CVD configuration a relatively high deposition rate can be achieved while obtaining desired levels of coating uniformity. Deposition approaches are described to place one or more inorganic layers onto a release layer, such as a porous, particulate release layer. In some embodiments, the release layer is formed from a dispersion of submicron particles that are coated onto a substrate. The processes described can be effective for the formation of silicon films that can be separated with the use of a release layer into a silicon foil. The silicon foils can be used for the formation of a range of semiconductor based devices, such as display circuits or solar cells.

### CROSS REFERENCE TO RELATED APPLICATIONS

This application claims priority to copending U.S. provisional patent application Ser. No. 60/934,793 filed on Jun. 15, 2007 to Hieshnair et al., entitled “Sub-Atmospheric Pressure CVD,” and to copending U.S. provisional patent application Ser. No. 61/062,398 filed on Jan. 25, 2008 to Hieslmair et al., entitled “Deposition Onto a Release Layer for Synthesizing Inorganic Foils,” both of which are incorporated herein by reference.

### FIELD OF THE INVENTION

The invention relates to deposition at sub-atmospheric pressures using chemical vapor deposition. Furthermore, the invention relates to reactive deposition approaches, such as chemical vapor deposition and light reactive deposition, onto a release layer for the formation of an inorganic foil that can be separated from the release layer. Corresponding methods and applications of the inorganic foils are described, in particular for foils formed from elemental silicon.

### BACKGROUND OF THE INVENTION

Several approaches have been used and/or suggested for the commercial deposition of the functional coating materials. These approaches include, for example, flame hydrolysis deposition, chemical vapor deposition, physical vapor deposition, sol-gel chemical deposition, light reactive deposition and ion implantation. Flame hydrolysis and chemical vapor deposition have been commercialized in the production of optic glass and corresponding elements. Chemical vapor deposition and physical vapor deposition have been widely used in the electronics industry generally in combination with photolithography.

Semiconductor materials are widely used commercial materials for the production of a great many electronic devices. Silicon in its elemental form is a commonly used semiconductor that is a fundamental material for integrated circuit production. Single crystal silicon is grown in cylindrical ingots that are subsequently cut into wafers. Polycrystalline silicon and amorphous silicon can be used effectively for appropriate applications.

Various technologies are available for the formation of photovoltaic cells, e.g., solar cells, in which a semiconducting material functions as a photoconductor. A majority of commercial photovoltaic cells are based on silicon. With non-renewable energy sources selling at high prices, there is continuing interest in alternative energy sources. Furthermore, renewable energy sources do not produce green house gases that can contribute to global warming. Increased commercialization of alternative energy sources relies on increasing cost effectiveness through lower costs per energy unit, which can be achieved through improved efficiency of the energy source and/or through cost reduction for materials and processing. Thus, for a photovoltaic cell, commercial advantages can result from increased energy conversion efficiency for a given light fluence and/or from lower cost of producing a cell.

### SUMMARY OF THE INVENTION

In a first aspect, the invention pertains to a method for forming an inorganic layer on a release layer supported on a substrate. The method comprises depositing an inorganic layer onto a porous, particulate release layer using chemical vapor deposition. In some embodiments, the substrate can be heated to facilitate the reaction at the surface. In additional or alternative embodiments, the method comprises moving the substrate with the release layer through a reactant stream from a nozzle to react at the release layer. The porous, particulate release layer can be formed, for example, by a light reactive deposition process or by coating a submicron particle dispersion onto the substrate surface. The chemical vapor deposition on the porous, particulate release layer can be enhanced with a plasma, hot filament or other energy source.

In a further aspect, the invention pertains to a method for depositing an inorganic layer. In some embodiments, the method comprises depositing an inorganic material using chemical vapor deposition onto a substrate that is moving relative to a flow of reactants delivered from a nozzle inlet in a reaction chamber with a sub-atmospheric pressure, such as from about 50 Torr to about 700 Torr and at a pressure below ambient pressure. The substrate can be heated to a temperature to induce the reaction at the substrate surface. The reactants can comprise silanes that react to form elemental silicon on the substrate surface. The surface of the substrate can have a release layer such that a subsequently deposited layer can be removed following deposition.

In another aspect, the invention pertains to a layered structure comprising a substrate, a powder layer on the substrate and an approximately dense silicon layer deposited onto the powder layer wherein the silicon layer has a thickness from about 2 microns to about 100 microns.

In additional aspects, the invention pertains to a method for forming an inorganic layer on a release layer in which the method comprises forming a power coating on a substrate and depositing an inorganic composition onto the powder coating. The formation of the powder coating comprises depositing a particle dispersion onto a substrate. The step of depositing of the inorganic composition is performed from a reactive flow in which the reactive flow is initiated from an inlet of nozzle directed at the substrate. The submicron particles can comprise a ceramic composition. The coating of the submicron particles can be performed by spin coating, spray coating or other suitable coating process. The reactive deposition can be driven with heat from a heated substrate such that a chemical vapor deposition process takes place with or without plasma or other energetic enhancement. In other embodiments, the reaction is driven by a light beam such that the light reactive deposition product is directed at the particle coated release layer. The dispersion liquid generally is evaporated prior to performing the reactive deposition onto the particle coating.

### BRIEF DESCRIPTION OF THE DRAWINGS

FIG. 1 is a schematic perspective view of a chamber for the performance of scanning sub-atmospheric pressure CVD deposition.

FIG. 2 is a sectional bottom view of a reactant delivery nozzle with elongated slits for delivering a reactant flow blanketed by inert shielding gas or an exhaust flow.

FIG. 3 is a sectional bottom view of a reactant delivery nozzle with five slots which can accommodate reactant delivery, optional shielding gas and optional exhaust passages.

FIG. 4 is a schematic layout of a reactant delivery system for delivering reactants to an inlet for a reactive deposition process.

FIG. 5 is a schematic layout of a deposition line with a plurality of deposition chambers connected with a transportation system.

FIG. 6 is a schematic perspective view of a deposition chamber for spatially sequential deposition using light reactive deposition and scanning sub-atmospheric pressure CVD.

FIG. 7 is a cut away perspective view of a specific embodiment of a deposition chamber with a single reactant delivery nozzle that can be used selectively used for light reactive deposition and scanning sub-atmospheric pressure CVD deposition.

FIG. 8 is a sectional perspective view of a silicon over-layer on a release layer.

FIG. 9 is a sectional side view of an alternative embodiment of a silicon layer on a release layer.

FIG. 10 is a sectional side view of a second alternative embodiment of a silicon layer on a release layer.

FIG. 11 is a top view of a representative photograph of a coated substrate with a release layer, silicon film and silicon nitride layers on the top and bottom of the silicon layer following a zone melt recrystallization step.

FIG. 12 is a top view of the coated substrate of FIG. 11 with a glass sheet laminated to the coating.

FIG. 13 is a top perspective view of the silicon foil separate from the substrate in association with the glass plate used for separation.

### DETAILED DESCRIPTION OF THE INVENTION

Deposition techniques based on reactive flows have been incorporated into formats to achieve surprising capability with respect to the efficient formation of significant coating materials as well as inorganic foils. In particular, it has been found that sub-atmospheric chemical vapor deposition (CVD) onto a moving substrate can be used effectively to deposit coatings with a balance between achieving a high rate of deposition and the high quality of the coating. Furthermore, it has been found generally that CVD can be performed onto a release layer. The release layer can have properties that provide for the separation of the coating as an inorganic foil, and it has been found that CVD can be performed onto a release layer while preserving the ability to fracture the release layer to form an inorganic foil. In some embodiments, deposition based on reactive flow can be performed onto a release layer that was formed using dispersion of submicron particles. The particle dispersion can be coated onto a substrate into a smooth coating that provides a reasonable surface for reactive deposition of a coating. While a range of inorganic foils and inorganic coatings can be formed using the techniques described herein, the techniques are effective in particular for the formation of elemental silicon foils and coatings. Elemental silicon is an important commercial material for a range of commercial application. In particular, the elemental silicon foils and coatings can be used as semiconductors within electronic devices, optical-electronic devices, such as displays, and photovoltaic devices.

In a directed flow-based deposition approaches, a reactive flow is initiated from an aperture that is aimed to generate a flow that is directed toward a substrate. Exhausts are placed to remove the flow that is deflected from the substrate following deposition of a product material. Reaction takes place within the flow and/or at the substrate surface. In light reactive deposition, the reactant flow passes through a light beam to produce a product flow downstream from the light beam. Chemical vapor deposition (CVD) is a general term to describe the decomposition or other reaction of a precursor gas, e.g., silane, at or immediately adjacent the surface of a substrate. The substrate can be heated to help drive the reaction. Atmospheric pressure CVD can be used to deposit layers of material at faster rates relative to low pressure processes. High vacuum CVD can be used to grow thin high quality films. As described herein, CVD is demonstrated with deposition onto a release layer such that the substrate can be subsequently removed and optionally reused.

High vacuum CVD and traditional sub-atmospheric CVD are generally performed in a non-directed flow configuration. In contrast, reactants are flowed into the chamber to create a reactive environment. The substrate is then coating simultaneously along the entire substrate surface, in contrast with directed flow-based deposition where different portions of the substrate are coated sequentially. Atmospheric pressure CVD has involved flow-based deposition onto a moving substrate. However, the flow and exhaust considerations are significantly different at atmospheric pressure where the deposition zone is generally open to the atmosphere.

As described herein, apparatus designs have been developed that provide for sub-atmospheric CVD in a directed flow-based format. The substrate can be scanned past the reactant flow to form a coating based on chemical reaction at or near the substrate surface. One or more exhausts can be appropriately positioned along the reaction chamber to collect flow that deflects from the substrate surface. The coating can be deposited at a high rate while maintaining good control on the coating properties.

For thicker silicon films with thicknesses greater than a few microns, atmospheric pressure CVD can be performed onto a heated substrate, for example, at high temperatures ranging from 600° C. to 1200° C. The substrate holder can be appropriately designed to operate at the desired high temperatures. For example, appropriate ceramic holders are commercially available for appropriate temperature ranges. These conditions provide a high deposition rate which is important for such thick films. However, it has been discovered that the deposition can be controlled better with a more uniform thin film product when the deposition is performed at sub-atmospheric pressures while still achieving relatively high rates. A secondary reactant, as described further below, can be added to the reactive flow to form silicon oxide, silicon nitride, silicon oxynitride, silicon carbide, silicon carbonitride, combinations thereof and mixtures thereof. Other compositions can be similarly deposited by CVD using appropriately selected reactants and appropriate conditions at the substrate.

Light reactive deposition is a directed flow-based deposition process in which the reactive flow passes through a light beam that drives the reaction to form a product flow that is directed toward a substrate. Light reactive flow processes, such as light reactive deposition, feature a flowing reactive stream from a chamber inlet that intersects a light beam at a light reaction zone to form a product stream downstream from a light reaction zone. The intense light beam heats the reactants at a very rapid rate. While a laser beam is a convenient energy source, other intense light sources can be used in light reactive deposition. Light reactive deposition can be used itself for the deposition of a porous particulate release layer. However, light reactive deposition is also can be used to deposit a denser layer over a release layer. Thus, the reaction conditions and deposition parameters can be selected to change the nature of the coating with respect to density, porosity and the like. Light reactive deposition onto a release layer is described generally in U.S. Pat. No. 6,788,866 to Bryan, entitled “Layer Material and Planar Optical Devices,” incorporated herein by reference. As described herein, in some embodiments, light reactive deposition can be performed onto a release layer formed from a dispersion of submicron particles, in contrast with a fused particle release layer formed using light reactive deposition.

Light reactive deposition can be used in the production of a large range of product materials. Reactant delivery approaches provide for a wide range of reaction precursors in gaseous, vapor and/or aerosol form, and the composition of the product material generally is a function of the reactants as well as the reaction conditions. Light reactive deposition can be used to form highly uniform coatings of materials, optionally comprising dopant(s)/additive(s) and/or complex composition(s). Thus, the composition and material properties of the corresponding porous, particulate coating can be adjusted based on the features of the light reactive deposition approach.

For some applications, it can be desirable to be able to separate a thin overcoat film on a release layer into thin foil of silicon or other inorganic material that can then be subjected to further processing. In particular, it has been found that the thin silicon film can be successfully formed onto a porous release layer. Upon the fractioning of the porous release layer, the thin inorganic foil can become a freestanding structure. While the use of a release layer makes it feasible to form a freestanding structure, the inorganic sheet can be relatively fragile, so that it can be desirable to generally support the sheet releasably on a substrate. Thus, the sheet can be releasably held to enable transfer of the structure from one substrate to another as desired. For example, an adhesive holding the sheet onto a substrate generally can be released using a reasonable amount of force or a solvent.

The term freestanding refers herein to the transferability, and the “freestanding” structure may not actually be unsupported at any time. The term freestanding herein is given a broad interpretation that includes releasably bound structures with the ability to transfer the layer even though the “freestanding” foil may never actually be separate form a support substrate since the continual support of the foil can reduce the incidence of damage. Freestanding does not imply the film can support its own weight. Generally, the substrates can be reused after fracture of the release layer and removal of the inorganic foil. The substrate surface can be cleaned/polished to remove remnants of the release layer such that the substrates can be reused. Since the substrate can be reused, high quality substrates can be used economically.

The release layer can have distinct properties that distinguish it from a layer above and a substrate below. The term substrate is used in the broad sense of the material surface contacting the release layer on which the release layer was deposited, whether or not the substrate surface layer was itself deposited as a coating on a further underlying substrate. The release layer may differ from the layer above and the substrate below with respect to composition and/or properties, such as density, such that it is susceptible to fracture.

With respect to the release layer as a fracture layer, the release layer generally has a substantially lower density than either the underlying substrate or the overcoat. The lower density of the fracture layer can be a result of the deposition process and/or due to processing following deposition. As a result of the lower density, the release layer generally can be fractured without damaging the substrate or overcoat.

In some embodiments, the composition of the release layer and the overcoat layer are different such that the compositional differences can be exploited to facilitate the function of the release layer. In some embodiments, the different compositions can be selected such that the release layer and the overcoat layer have different consolidation temperatures. Specifically, the release layer can have a higher consolidation temperature so that the overcoat can be densified through heating the structure while the release layer remains substantially unconsolidated with a lower density. The consolidation of the overcoat layer and the substantial non-consolidation of the release layer can result in a substantial density difference between the release layer and the overcoat material that can be exploited to fracture the release layer. The use of differential consolidation temperatures for processing adjacent layers into different density materials and fracturing of the release layer is described further in U.S. Pat. No. 6,788,866 to Bryan, entitled “Layer Materials and Planar Optical Devices,” incorporated herein by reference.

However, in some embodiments, the release layer functions through the specific properties of the composition rather than density. Specifically, the composition of the release layer is distinct from the composition of the overcoat layer such that further processing can remove or damage the release layer. For example, the release layer can be formed from a soluble material that can be dissolved to release the overcoat material. A range of inorganic compositions are suitable for a release composition. For example, a metal chloride or metal nitrate can be deposited using an aerosol without any further reactants so that a coating of unreacted metal compound are deposited in the process, although in other embodiments the release layer composition can be a reaction product within the coating stream.

The porous, particulate layer can comprise essentially unfused submicron particles or a fused porous network of submicron particles deposited on a substrate surface. Thus, the porous release layer can be a soot from reactive deposition, which may be in the form of a fused particle network, or a powder layer, which can be deposited, for example, with a liquid dispersion of submicron particles. The composition of the porous, particulate layer can comprise a high melt temperature material, such as silicon oxide, silicon nitride, silicon oxynitride, silicon carbide, silicon carbonitride, combinations thereof and mixtures thereof. The release layer generally covers an entire surface of the substrate, although in other embodiments, the release layer can cover a selected portion of the substrate surface.

In some embodiments, it can be desirable to deposit two or more soot layers. For example, a second soot layer on the first soot layer can provide a transition layer with respect to dense layers deposited subsequently. Thus, the second soot layer can comprise primary particles with a smaller average particle size. Due to the smaller average particle size, the second soot layer can generally have a higher density. In alternative or additional embodiments, the second layer can have a different composition than the first soot layer. Thus, it may be desirable to select a composition for the second soot layer that has a lower flow or sintering temperature. Thus, the second soot layer can densify partially or completely at the temperatures of the CVD deposition or during a subsequent zone melt recrystallization or other post deposition heating step. A lower softening or sintering temperature can be accomplished through the selection of the material composition, such as through the selection of a dopant, although the small particle size can lead to a lowering of the softening temperature. If the second soot layer densifies into a dense layer during processing, this layer can be incorporated into the device formed from the structure.

The release layer can be deposited using a variety of techniques which provide appropriate low levels of contamination and uniform layers. Whether or not the porous, particulate layer comprises fused or unfused particles, in some embodiments it is desirable for the particles or porous structure to involve submicron particles such that the surface of the porous layer is not undesirably uneven such that the subsequently deposited layer deposits relatively flat. In general, the porous, particulate release layer can have any reasonable thickness, although it may be desirable to use a thickness that is not too large so that resources are not wasted.

A specific suitable method for delivering submicron particles to form the release layer involves light reactive deposition. In some embodiments, the particles are deposited in the form of a powder coating, i.e. a collection of unfused submicron particles or a network of fused or partly fused submicron particles in which at least some characteristics of the initial primary particles are reflected within the coating. With respect to a reactive deposition process for forming a release layer, the processing parameters can be adjusted to deposit the release layer at a significantly lower density than the overcoat layer. The differences in density can be adjusted to yield the desired differences in mechanical strength such that the release layer can be fractured to form the overcoat as a freestanding structure, e.g., a releasably supported structure. For example, the release layer can be deposited as a coating with a density corresponding with a release layer porosity of at least about 40 percent. The release layer can have other functions in addition to the mechanical release function because the release layer can have or can be engineered to have desirable characteristics. For example, the porous, particulate layer can have a high surface area, can be mechanically compliant, and can be engineered to be slightly or partially sinterable at high temperatures. Also, the layer can have low thermal conductivity.

While in some embodiments the release layers are themselves formed using a reactive deposition, in alternative embodiments, the release layer is formed from a dispersion of submicron particles. There are several significant aspects to making this feasible. To form a good quality film on the release layer, the release layer should be relatively smooth, and it should have a reasonable packing density so that the deposited over-layer does not penetrate too far within the release layer. The use of particles with a submicron average primary particle size is significant with respect to forming a smooth release layer from the particles.

Furthermore, the particles can be well dispersed into a liquid for forming the release layer. The particles can be delivered with or without surface modification. The dispersions can be delivered using a range of delivery approaches, such as spray coatings, dip coating, roller coating, spin coating, printing and the like.

With appropriate selection of a release layer, a release layer can provide a mechanism to release an overcoat material with one or more layers having a desired composition and structure as a freestanding inorganic foil. In some embodiments, the overcoat material can comprise silicon/germanium-based semiconductor structures. The material may or may not comprise a selected amount and composition of a dopant. Appropriate processing steps can be performed before or after release from the substrate depending on the desired objectives and processing convenience for forming the ultimate device.

In some embodiments, reactive deposition apparatuses for deposition onto a release layer can be adapted from commercial high vacuum CVD apparatus and atmospheric pressure CVD apparatuses. In further embodiments, scanning sub-atmospheric pressure CVD apparatuses are described herein. Furthermore, a dual function chamber can be used in which light reactive deposition is performed to deposit a release layer and a sub-atmospheric pressure CVD deposition is performed in the reaction chamber with the light beam turned off and with the substrate appropriately heated. The substrate is moved relative to the flow to scan the product coating across the substrate surface. The reaction conditions and the flow can be adjusted to achieve a coating with desired properties.

The scanning sub-atmospheric pressure CVD apparatus generally comprises a chamber, a substrate support, an inlet operably connected to a reactant supply, an exhaust and a transport system to translate the substrate support relative to the inlet. The chamber isolates the reaction such that the reaction takes place within a selected pressure range, generally from about 50 Torr to about 650 Torr. The chamber pressure is generally below the ambient pressure, which implies that flow through the chamber is maintained through pumping or blowing gasses, vapors and/or particulates from the chamber to maintain the desired chamber pressure. The substrate support can be configured to hold the substrate below the inlet such that the reactants intersect the substrate from above to facilitate the handling of larger substrates, although in some embodiments the substrate is supported above the inlet. In some embodiments, the substrates can have large surface areas, such as greater than 400 cm², to form correspondingly large coatings for appropriate applications.

The reactant supply system operably connected to the inlet can comprise one or more reactants for delivery as a gas, vapor or an aerosol, optional inert diluent gases as well as optional secondary reactants that can be used to alter the reactive environment within the chamber. Inert shielding gas can be delivered adjacent the reactive flow. One or more exhaust outlets can remove un-reacted reactants and un-deposited products as well as generally maintaining the chamber pressure within a selected range. In some embodiments, the reactant delivery inlet can have an elongated shape with the long dimension corresponding approximately with, or slightly larger than, the width of the substrate scanned past the inlet so that the substrate can be coated with one scan past the inlet.

The transport system moves the substrate holder relative to the reactant inlet through the movement of the reactant inlet relative to the chamber and/or through the movement of the substrate holder relative to the chamber. The transport system provides for the scanning of the coating deposition across the substrate. The transport system can comprise an appropriate conveyor, stage or the like. The transport system can be correspondingly associated with a substrate handling system such that the deposition chamber can be integrated into a production line with an appropriate supply of substrates being fed into the coating chamber and coated substrates being delivered into to subsequent processing stations. For the processing of large area substrates, the CVD chambers can be made correspondingly large for the coating of the substrate with a single pass through the chamber past the reactant inlet, although multiple passes can be used to deposit multiple layers.

For embodiments involving the deposition onto a release layer, the release layer can be deposited prior to the deposition of the over-layer with in the same reaction chamber or within sequential reaction chambers. For embodiments based on light reactive deposition of the release layer, the reactants can be delivered through the same nozzle that is subsequently used for a CVD deposition of an over-layer. For these embodiments, the substrate is scanned past the inlet at least twice, once to deposit the release layer and once to deposit the over-layer. A light beam, e.g., generated by a laser, can be used to drive the light reactive deposition to deposit the release layer, and the light beam is turned off for the CVD deposition.

In other embodiments, a separate inlet is used to deliver the reactants through a light beam to deposit the release layer using light reactive deposition while a separate inlet delivers the reactants for the CVD over-layer deposition. If the reaction chamber pressures are compatible, the light reactive deposition reaction and the CVD deposition can be performed in the same reaction chamber with the transport system directing the substrate first past the inlet for depositing the release layer and then past the inlet for depositing the over-layer. In further embodiments, the release layer is deposited by light reactive deposition in a first reaction chamber and the CVD deposition onto the release layer is performed in a sequentially positioned reaction chamber. For the deposition on a plurality of over-layers, the additionally over-layer(s) can be deposited using a selected reactive deposition approach such as light reactive deposition or CVD using one of the inlets used for the release layer or the other over-layer or using a separate inlet appropriately positioned.

For embodiments in which the release layer is formed using a particle dispersion, the release layer can be formed in the reaction chamber or external to the reaction chamber in which the over-layer is formed. For example, the release layer can be formed using spray coating or other suitable approach prior to performing the deposition of the over-layer. An appropriate nozzle of other inlet configuration can be used to perform the spray coating of the like. The dispersant used to disperse the particles for the deposition can be removed by evaporation using the chamber exhaust. The heating to prepare the structure for the deposition step can further act to remove the solvent.

It has been found that chemical vapor deposition can be effectively performed onto a porous, particulate release layer such that thin inorganic films, such as films comprising silicon/germanium, can be separated from the structure. In this way, the inorganic foils can be transferred appropriately for further processing, for example, into solar cells, flat panel displays or other devices. In order to reduce the use of silicon in solar cells relative to wafer based cells, thin foils of polycrystalline silicon can be effectively processed into efficient solar cells. A porous, particulate release layer can also be used to form inorganic foils with other desired compositions.

In some embodiments, a deposition method involves the growth of a silicon foil or other inorganic foil with a CVD technique on top of a porous, particulate release layer, which can be on a reusable ceramic substrate. In some embodiments, the resulting silicon foil can have a thickness of no more than about 100 micron, and the resulting silicon layer can be an approximately non-porous polycrystalline silicon. The inorganic foil can become freestanding after it detaches along the release layer. The inorganic foil can comprise one layer or a plurality of layers, such as two layers, three layers, four layers or more layers, in which the different layers can differ in composition. Some specific layered structures desirable for silicon foils are described further below. The release layer also aids in relief of strain due to thermal expansion differences within the structure. Freestanding foils also can have advantages in processing into solar cells over films permanently deposited on to any substrate for some processing configurations.

The scanning CVD processes described herein onto a porous, particulate release layer can be performed at sub-atmospheric pressures, although other embodiments can be performed within different pressure ranges. Higher throughputs of reactants can be achieved at atmospheric pressures, but for some embodiments with a desired high uniformity of the deposited inorganic layer, the desired properties of the deposited layer can be achieved at sub-atmospheric pressures of about 50 Torr to about 650 Torr, or a selected sub-range within this explicit range. In some embodiments, desirable results can be obtainable up to 700 Torr as long as the ambient pressure is above this value. The present approach for sub-atmospheric deposition is in contrast with the approach described in U.S. Pat. No. 5,627,089 to Kim et al., entitled “Method for Fabricating a Thin Film Transistor Using APCVD,” incorporated herein by reference, where deposition can be performed at 400-500 Torr in an oven with the reactant filing the oven chamber. Traditional atmospheric pressure CVD apparatuses are described further in U.S. Pat. No. 5,626,677 to Shirahata, entitled “Atmospheric Pressure CVD Apparatus,” and published U.S. patent application 2006/0141290A to Sheel et al., entitled “Titania Coatings by CVD at Atmospheric Pressure,” both of which are incorporated herein by reference.

The temperature of the substrate can be selected to provide an appropriate reaction of the silane or other CVD reactant flow at the substrate surface, and the selected temperature can be dependent on the deposition rate. In general, the substrate can be heated with a heater below the substrate that heats the top surface through conduction and/or with a radiative heater that heats the top surface from above. The CVD deposition can be plasma enhanced, which may provide for lower substrate temperatures for a given deposition rate. Additionally, a hot filament or other energy source can be used to enhance the surface reaction similar to other CVD deposition approaches. Suitable substrates include, for example, silicon substrates, silica substrates, silicon carbide substrates and other highly polished ceramic materials. For embodiments involving a release layer, since the substrate can be reused after fracture of the release layer and removal of the foil, high quality substrates can be used economically. In general, suitable porous, particulate coatings have a density of no more than about 50% of the density of the material when the material is fully densified and non-porous, and other subranges of density within this specific range is also hereby disclosed.

An overcoat structure with one or more layers formed over a release layer generally can be subjected to one or more processing steps to prepare the material for incorporation into a particular device. These additional processing steps, such as annealing, re-crystallization, or the like, can be performed with the overcoat structure attached to the substrate, with the structure separated at the release layer, or with some of the processing steps performed with the structure attached to the substrate and some of the processing steps performed with the structure separated from the substrate. After separation of the inorganic foil from the release layer, additional processing can involve association of the freestanding inorganic foil with a holding surface. The holding surface may be a final location of the inorganic foil within a device for use, or the holding surface may be a temporary location to facilitate the performance of one or more processing steps. If the holding surface is temporary, the inorganic foil can be temporarily secured to the holding surface with an adhesive, suction, static electricity or the like. The association with a holding surface can mechanically stabilize the inorganic foils during particular processing steps.

For silicon/germanium based semiconductor foils, it can be desirable to recrystallize the foil to increase the crystal size to correspondingly improve the electrical properties of the semiconductor. Zone melt recrystallization can be effectively performed with the silicon/germanium foil associated with the release layer. The release layer, an optional under-layer and an optional cap layer can be formed from higher melting ceramic compositions, such as silicon oxide, silicon nitride, silicon oxynitride, silicon carbide, silicon carbonitride, aluminum oxide Al₂O₃, blends thereof, silicon rich compositions thereof, and combinations thereof.

For the formation of a photovoltaic cell as well as other appropriate devices, it is desirable to have texture on the top and/or bottom surfaces to increase the optical path lengths within the material. Texture can be introduced with a textured substrate with deposition over the textured substrate. Alternatively, texture can be introduced in a deposited surface in the deposition process or a subsequent etching or other surface modification step. The texturing can be random, pseudo-random, or ordered. The porosity of the release layer can also be used to impart a rough texture on subsequent layers.

The availability of thin, large area silicon/germanium-based semiconductor sheets provide for the production of large, high efficiency solar cells, displays as well as other devices based on these semiconductors sheets. Individual solar cells can be cut from a larger sheet as part of a solar cell panel formation. In a solar cell panel, there is a plurality of individual cells that are connected in parallel and/or in series. The cells connected in series increase the output voltage of the panel since the cells connected in series have additive potentials. Any cells connected in parallel provide increased current. Reasonably positioned cells on a panel can be electrically connected using appropriate electrical conductors. The wired photovoltaic panel can be appropriately connected then to an external electrical circuit.

In addition, the thin sheets of silicon/germanium-based semiconductor provide useful substrates for display components. In particular, the semiconductor sheet can be a substrate for the formation of thin film transistors and/or other integrated circuit components. Thus, the thin semiconductor sheets can be large format display circuits with one or more transistor associated with each pixel. The resulting circuits can replace structures formed by silicon on glass processes. The formation of large area semiconductor foils into display circuits is described further in published U.S. patent application 2007/0212510A to Hieslmair et al., entitled “Thin Silicon or Germanium Sheets and Photovoltaics Formed From Thin Sheets,” incorporated herein by reference.

In general, the semiconductor sheets described herein provide a cost effective approach to form a range of devices with a reduction in the use of material and a convenient processing format. The uniformity of the material and the speed of production are significant parameters for efficient and cost effective commercial production. The amenability of the semiconductor sheets to efficient forms of further processing make the sheets suitable for efficient formation of a range of integrated circuit and other structures.

Sub-Atmospheric CVD with Directed Flow-Based Deposition

It has been discovered that CVD can be effectively performed in a directed flow format at sub-atmospheric pressures. The directed flow to initiate a reactant stream can be directed through an orifice with a large aspect ratio, such as a slit, so that a large area can be coated with the reactive deposition with a single translation past the reactant inlet. Suitable exhaust can be positioned to remove un-reacted compositions and to maintain the chamber pressure within a selected range.

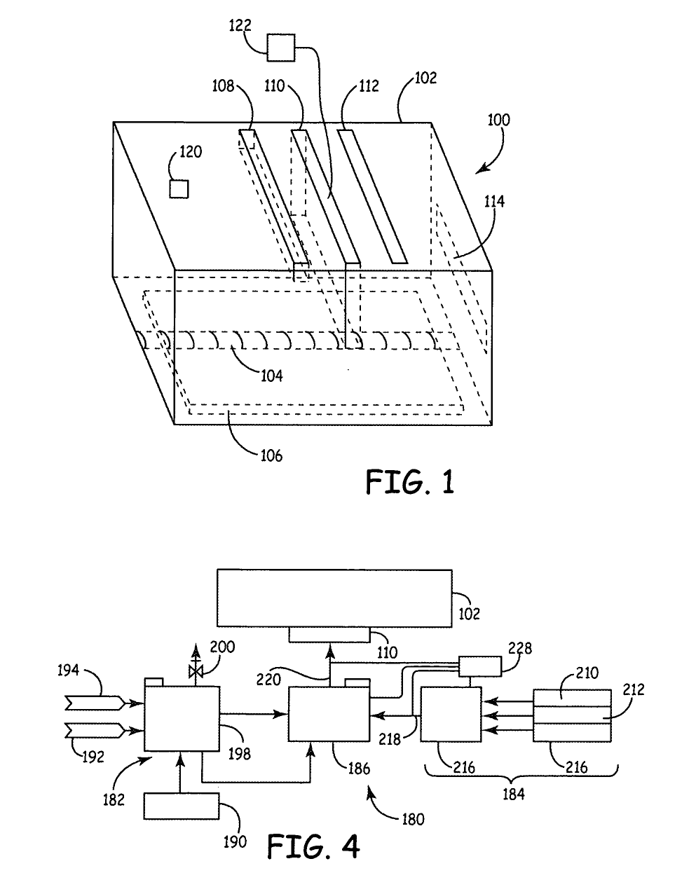

A schematic drawing of an apparatus for performing scanning sub-atmospheric CVD is shown in FIG. 1. Referring to FIG. 1, scanning sub-atmospheric pressure CVD apparatus 100 comprises chamber 102, a transport system 104, a bottom heater 106, a radiant heater 108, a reactant nozzle 110, and exhausts 112, 114. Chamber 102 is sealed from the surrounding atmosphere to maintain the pressure in the chamber within a selected range for the deposition. Chamber 102 can be formed from suitable materials, such as metals, ceramics and combinations thereof Chamber 102 can comprise one or more pressure gauges 120 and/or other sensors, such as a temperature sensor.

Transport system 104 can be designed to interface with a substrate to move the substrate through chamber 102. A substrate support, such as a chuck or the like, can be associated with the substrate for interfacing with transport system 104, or a substrate support can be integral with the transport system such that the substrate is delivered separately from the substrate support as it is moved into and out from the chamber. The substrate support generally can be any appropriate platform to hold the inorganic film and associated structure at the temperatures of the chamber. Transport system 104 can comprise, for example, a conveyor belt or a stage or platform that is connected with an appropriate moving element, such as a chain drive or the like.

Bottom heater 106 can comprise, for example, an appropriate heater known in the art, such as a resistance heater or a radiant heater. The heater can be selected based on the target temperature and other design considerations. For high temperatures, a boron nitride heater can be used. Radiant heater 108 can heat the top surface of the substrate with infrared and/or other optical frequencies. As described below, a radiant heater can be particularly useful for the heating of porous, particulate release layers to heat the release layer for a CVD deposition of an over-layer. Radiant heater 108 can comprise a strip heater that can simultaneously heat a stripe of the substrate. Specifically, radiant heater 108 can comprise a focused halogen or xenon lamp, an inductive heater, carbon strip heater, rastered laser, or the like. An appropriate linear reflector with a parabolic cross section can be used to reflect and focus light on the surface with less heat being dissipated through the chamber. In alternative or additional embodiments, radiant heater 108 can comprise a diode array, which can be a laser diode array.

Nozzle 110 generally has an orifice that functions as an inlet into chamber 102. The nozzle further connects to a reactant delivery system 122. In some embodiments, the inlet of nozzle 110 has an elongated shape, such as a slit, so that the coating can be deposited from the flow simultaneously along a stripe of the substrate. As the substrate moves relative to the nozzle, the stripe is swept across the substrate to cover the substrate with a single pass. In general, the inlet can have an aspect ratio of the length divided by the average width of at least about 3, in further embodiments at least about 5, and in other embodiments, from about 10 to about 1000. A person of ordinary skill in the art will recognize that additional ranges of aspect ratios within the explicit ranges above are contemplated and are within the present disclosure.

Specific designs of nozzle 110 for use in a scanning sub-atmospheric CVD apparatus can be adapted from designs for other systems. For example, nozzles can be adapted form designs for nozzles for Light Reactive deposition nozzles. See, for example, U.S. Pat. No. 6,919,054 to Gardner et al., entitled “Reactant Nozzles Within Flowing Reactors,” incorporated herein by reference. Furthermore, nozzle 110 can be adapted from atmospheric pressure CVD nozzles. See, for example, published U.S. patent application 2005/0183825A to DeDontney et al., “Modular Injector and Exhaust Assembly,” incorporated herein by reference.

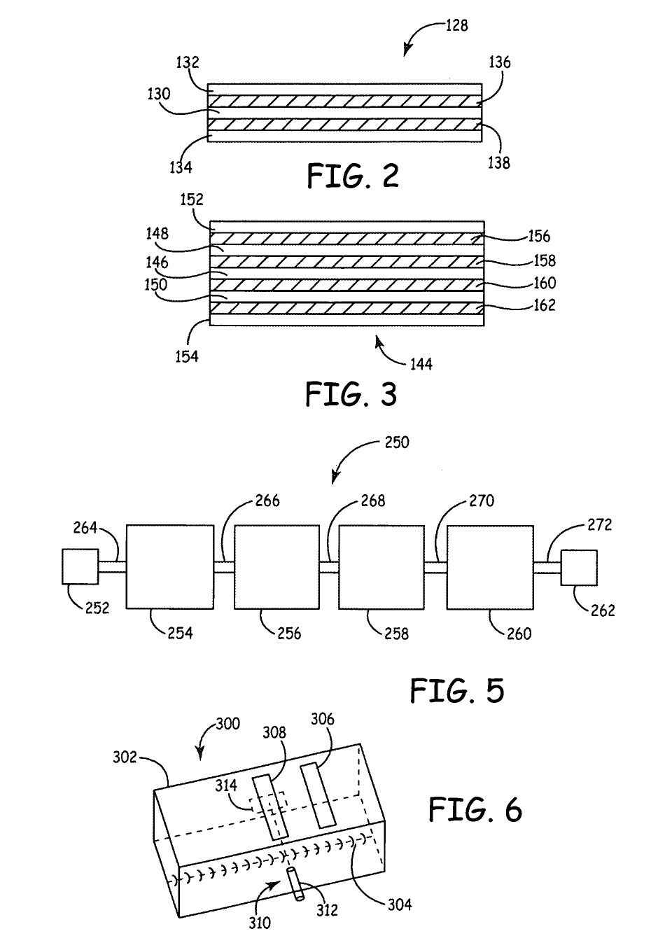

An example of an inlet nozzle embodiment is shown in FIG. 2. Nozzle 128 comprises a central reactant inlet 130, two adjacent gaps 132, 134 spaced from inlet 130 with plates 136, 138. Central reactant inlet 130 has a fluid connection with a reactant delivery system. Gaps 132, 134 can be used to deliver secondary reactants or shielding gas, or to remove gases, vapors and/or particulates to function as exhausts. In particular, if an inert shielding gas is delivered through gaps, 132, 134, the shielding gas facilitates the deliver of the reactant stream with less spreading of the flow. An alternative embodiment is shown in FIG. 3. Nozzle 144 comprises a central reactant inlet 146, shielding gas inlets 148, 150, exhaust gaps 152, 154 and spacing plates 156, 158, 160, 162. Additional embodiments can be adapted from these specific examples.

A specific embodiment of a reactant delivery system 122 is shown schematically in FIG. 4. As shown in FIG. 4, reactant delivery system 180 comprises a gas delivery subsystem 182 and a vapor delivery subsystem 184 that join a mixing subsystem 186. Gas delivery subsystem 182 can comprise one or more gas sources, such as a gas cylinder or the like for the delivery of gases into the reaction chamber. As shown in FIG. 4, gas delivery subsystem 182 comprises a first gas precursor source 190, a second gas precursor source 192 and an inert gas source 194. The gases combine in a gas manifold 198 where the gases can mix. Gas manifold can have a pressure relief valve 200 for safety.

Vapor delivery subsystem 184 comprises a plurality of flash evaporators 210, 212, 214. Each flash evaporator can be connected to a liquid reservoir to supply liquid precursor in suitable quantities. Suitable flash evaporators are available from, for example, MKS Equipment or can be produced from readily available components. The flash evaporators can be programmed to deliver a selected partial pressure of the particular precursor. The vapors from the flash evaporator are directed to a manifold 216 that directs the vapors to a common feed line 218. The vapor precursors mix within common feed line 218.

The gas components from gas delivery subsystem 182 and vapor components from vapor delivery subsystem 184 are combined within mixing subsystem 186. Mixing subsystem 186 can be a manifold that combines the flow from gas delivery subsystem 182 and vapor delivery subsystem 184. In the mixing subsystem 186, the inputs can be oriented to improve mixing of the combined flows of different vapors and gases at different pressures. A conduit 220 leads from mixing subsystem 186 to reaction chamber 102 through nozzle 110. An inert gas source can also be used to supply shielding gas to a nozzle for appropriate embodiments.

A heat controller 228 can be used to control the heat through conduction heaters or the like throughout the vapor delivery subsystem, mixing system 366 and conduit 400 to reduce or eliminate any condensation of precursor vapors. A suitable heat controller is model CN132 from Omega Engineering (Stamford, Conn.). Overall precursor flow can be controlled/monitored by a DX5 controller from United Instruments (Westbury, N.Y.). The DX5 instrument can be interfaced with mass flow controllers (Mykrolis Corp., Billerica, Mass.) controlling the flow of one or more vapor/gas precursors. The automation of the system can be integrated with a controller from Brooks-PRI Automation (Chelmsford, Mass.).

As shown in FIG. 1, exhaust 112 is located in an aligned position adjacent inlet nozzle 110. Thus, exhaust 112 is in position to remove unreacted compositions, undeposited product compositions and other compositions in the flow that reflect from the substrate surface. In some embodiments, another aligned exhaust is located on the other side of the nozzle so that inlet nozzle 110 has an exhaust nozzle on both sides. Exhaust 112 generally has an orifice that is an outlet for the exhaust system in which the outlet has a similar length as the inlet of nozzle 110. The width of the outlet can be selected to provide the desired degree of exhaust capacity. Exhaust 114 is shown in association with a rear wall of chamber 102. In alternative or additional embodiments, exhaust 114 can be placed in other locations along the walls, top surface or floor of chamber 102 to provide desired flow through the chamber. Furthermore, there can be 2, 3, 4 or more exhausts along the walls, floor and top surface of chamber 102. Exhausts 112, 114 generally are connected to conduits and subsequently to a pump, blower or other negative pressure device, which can be the same device or different devices for exhaust 112, 114, to maintain flow through the system and to maintain the chamber pressure within desired ranges. The exhaust system can further comprise filters, traps, scrubbers and the like.

In general, the scanning sub-atmospheric pressure CVD apparatus can operate at pressure ranges from about 50 Torr to about 700 Torr, in some embodiments from about 50 Torr (mmHg) to about 650 Torr, in further embodiments, from about 75 Torr to about 625 Torr, in additional embodiments from about 85 Torr to about 600 Torr, and in other embodiments form about 100 Torr to about 575 Torr, as well as all ranges between any of these ranges. A person of ordinary skill in the art will recognize that additional pressure ranges within the explicit ranges above are contemplated and are within the present disclosure. Furthermore, the chamber pressure is generally below the ambient pressure with the chamber being sealed from the ambient atmosphere. The deposition rates can be adjusted to achieve the desired coating properties. Thus, the scanning speed of the substrate past the reactant inlet can be adjusted as well as the flow rate of the reactants.

In the embodiments described above, the reactants are delivered form above and the material is deposited onto the top surface of the substrate. This is a convenient configuration for the handling of the substrates. However, the configuration can be reversed, which essentially amounts to an inversion of the various components relative to each other within the reaction chamber.

### Flow-Based Deposition Processes and the Deposition of Multiple Layers

For the production of a particular structure, generally a plurality of layers can be deposited. In some embodiments, one of these layers is a porous, particulate release layer. In additional or alternative embodiments, one or more of these layers may be deposited by scanning sub-atmospheric pressure CVD. These multiple layers can be deposited within a common reaction chamber or within separate reaction chambers or a combination thereof. If one or more reaction chambers are used, the multiple reaction chambers can be integrated into a common automated production line for the efficient handling of the substrates. One or more coating steps can be performed prior to introduction to the production line.

A schematic production line comprising a plurality of deposition chambers is depicted in FIG. 5. Production line 250 comprises a loading station 252, a first deposition system 254, a second deposition system 256, a third deposition system 258, a fourth deposition system 260, a collection station 262 and transfer sections 264, 266, 268, 270, 272. Loading station 252 comprises a substrate handling system for the placement of initial substrate, which can be uncoated or initially coated substrates, for introduction into the coating line. Generally, loading station 252 can handle a plurality of substrates. Loading station 252 may be able to accommodate pressurization of the station for the transfer of the substrates into a pressurized chamber with the use of a pressurized door that can be closed prior to altering the pressure of the transfer station for subsequent transfer of a substrate from the transfer station to first deposition chamber 254. Collection station 262 can be similar to loading station 252 in which collection station 262 collects coated substrates for further use and in which the pressure can be appropriately adjusted.

In general, deposition chambers 254, 256, 258, 260 can individually be configured for coating based on a particle dispersion, light reactive deposition, scanning sub-atmospheric pressure CVD, other appropriate deposition processes or combinations thereof. One specific embodiment is discussed for illustration. In particular, first deposition chamber 254 can be used to deposit a release layer onto an initial substrate. Suitable processes for the deposition of a release layer include, for example, light reactive deposition and deposition of a particle dispersion, as described further below. Second deposition chamber 256 can be used to deposit a first over-coat layer. Third deposition chamber 258 can be used to deposit a second over-coat layer, and fourth deposition chamber 260 can be used to deposit a top layer. In particular, third deposition chamber 258 can be used to deposit a silicon layer with adjacent layers deposited with second deposition chamber 256 and fourth deposition chamber 260. The silicon layer can be effectively deposited using scanning sub-atmospheric pressure CVD. Each deposition chamber can comprise a conveyor system to advance a substrate through the chamber and to accept a substrate from the previous unit on the system and to advance the coated substrate to a subsequent unit on the system.

Transfer stations 264, 266, 268, 270, 272 can comprise appropriate conveyor components to transport a substrate between adjacent processing units. Conveyor components can comprise a belt, stage or the like with a motor to drive the transfer. Transfer stations may also comprise pressure locks or the like to provide for the change in pressure between adjacent processing units if the processing units operate at different selected pressures. Appropriate pressure systems can be connected to the transfer stations to effectuate a desired pressure change with the pressure locks or the like generally closed.

While FIG. 5 depicts the system with 4 deposition chambers, the system can alternatively have 1, 2, 3, 5 or more deposition chambers. In additional, other processing stations can be included in the system to provide for other processing the produced structures in addition to deposition, such as heat treatments, chemical modification or the like. A plurality of processing stations linked in a substrate processing apparatus in which one processing station is an atmospheric pressure CVD apparatus is described further in U.S. Pat. No. 5,626,677 to Shirahata entitled “Atmospheric Pressure CVD Apparatus,” and U.S. Pat. No. 6,841,006 to Barnes et al., entitled “Atmospheric Substrate Processing Apparatus for Depositing Multiple Layers on a Substrate,” both of which are incorporated by reference. In contrast with the atmospheric pressure CVD systems of the above patents, the system of FIG. 5 and related embodiments are isolated from the ambient atmosphere and operate at less that atmospheric pressure.

In some embodiments, a plurality of deposition stations is incorporated into a single chamber. In particular, in some embodiments, different portions of a substrate can be processed simultaneously within the chamber. This can be particularly efficient for the processing of large substrates if the processing conditions for the two deposition stations are compatible. Similarly, more than two deposition stations, such as three or more processing stations can be located within a single chamber, which may or may not be configured for simultaneous deposition onto a single substrate.

Referring to FIG. 6, a deposition chamber is schematically shown that is configured to sequentially deposit a layer with light reactive deposition followed by a layer deposited using scanning sub-atmospheric pressure CVD, which can be deposited simultaneously onto a single large substrate at different locations on the substrate. Referring to FIG. 6, deposition system 300 comprises chamber 302, transport system 304, CVD nozzle 306, LRD nozzle 308 and optical system 310. Chamber 302 isolates the inside of the chamber from the ambient atmosphere such that a desired pressure can be maintained within chamber 302. Transport system 304 is configured to scan a substrate through the chamber past the deposition nozzles. CVD nozzle 306 establishes a CVD deposition position within the chamber 302. Similarly, LRD nozzle 308 establishes a light reactive deposition position within chamber 302. Optical system 310 is configured to direct a light beam such that flow from LRD nozzle 308 flows through the light beam. Optical system 310 comprises an optical conduit 312, which can further comprise a lens or telescopic optics, to direct light across chamber 302 to a beam dump or light meter 314.

If a substrate is transported from left to right within chamber 302 as shown in FIG. 6, a release layer can first be deposited using light reactive deposition, and an overcoat layer, such as elemental silicon, can be deposited over the release layer within chamber 302. The deposition stations can be positioned such that there is little or any interference with respect to the different coating processes. In some embodiments, the light reactive deposition station is replaced with a spray coating station for the formation of a release layer. Light reactive deposition has been performed with gas reactants, vapor reactants and/or aerosol reactants. The use of aerosol reactants for flowing reaction systems, especially for light reactive deposition, is described further in U.S. Pat. No. 6,193,936 to Gardner et al., entitled “Reactant Delivery Apparatuses,” incorporated herein by reference. In some embodiments, the aerosol is entrained in a gas flow, which can comprise an inert gas(es) and/or a gaseous reactant(s).

Furthermore, it has been found that a single nozzle can be used to sequentially perform a light reactive deposition step followed by a scanning sub-atmospheric pressure CVD step. The light beam is turned on for the light reactive deposition step and then turned off for the CVD step. Thus, in a first scan past the nozzle a release layer can be deposited using light reactive deposition, and in a second scan past the nozzle an over-layer can be deposited over the release layer. Additional layers can be deposited using either light reactive deposition or scanning sub-atmospheric CVD using additional scans. Thus, the transport system of the chamber is configured to have the ability to reverse direction. The scan direction during the deposition steps may or may not be reversed.

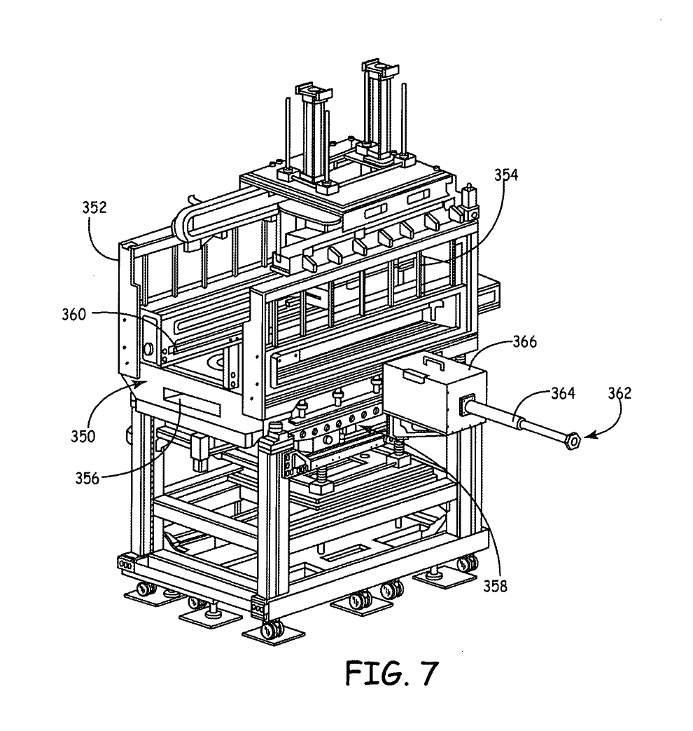

A specific embodiment of a deposition chamber configured for sub-atmospheric CVD and light reactive deposition is shown in FIG. 7. Deposition chamber 350 comprises chamber 352, a nozzle 354, a substrate slot 356 into chamber 352, a bottom heater 358, a translation module 360 and an optical system 362. Nozzle 354 is operably connected to a reactant delivery system, such as the system of FIG. 4, which can deliver reactants for both the light reactive deposition process and the scanning sub-atmospheric pressure CVD process. Substrate slot 356 is configured to receive a substrate from a substrate handling system and to move the substrate into the deposition chamber. Translation module 360 comprises a stage translated with a worm drive connected to a suitable motor that is configured to transfer rotational motion into translations motion. The stage receives a substrate through slot 356 and subsequently translates the substrate through chamber 352. Optical system 362 comprises a light tube 364 that can form a sealed light beam path from a CO₂ laser, and telescopic optics 366 that can change the beam diameter to a selected size.

### Release Layers

Release layers provide the ability to perform a deposition of an inorganic layer onto the release layer with the ability to separate the over-layer as an inorganic foil. A release layer has a property and/or composition that distinguish the release layer from adjacent materials. In general, a chemical and/or physical interaction can be applied to the release layer to remove or fracture the release layer to detach the subsequently deposited layers. The overcoat structure can be formed with one or more additional deposition steps and optionally with further processing while the structure is associated with the release layer. In some embodiments, the release layer is a porous, particulate layer. It has been found that CVD can be used to deposit an over-layer onto a porous, particulate release layer while maintaining the ability of the release layer to fracture to release the over-layer as an inorganic foil. A porous, particulate release layer can be formed using a reactive deposition approach, such as light reactive deposition, or through the deposition of a powder coating using a particle dispersion.

Suitable physical properties of a release layer can be, for example, low density, high melting/ softening point, low mechanical strength, large coefficient of thermal expansion or combinations thereof. For some embodiments, suitable chemical properties include, for example, solubility in a selected solvent. In addition, the material of the release layer generally should be inert with respect to the other materials in the structure at conditions of relevant processing steps, such as at high temperature in some embodiments. The selected properties of the release layer can be exploited to separate an over-layer(s) from the underlying substrate.

In general, the release layer can have an appropriate thickness within ranges described for other layers deposited by the reactive deposition approaches described herein. On one hand, since the release layer may not be used functionally once the overcoat is released, it may be desirable to keep the release layer thin to consume fewer resources. However, if the layer is too thin, certain properties, such as mechanical strength and separation of the over-coat layer from the substrate below the release layer, may be compromised. In general, a person of ordinary skill in the art can adjust the thickness to obtain desired properties of the release layer. In some embodiments, the release layer can have a thickness from about 50 nanometers (nm) to about 50 microns, in further embodiments from about 100 nm to about 10 microns and in additional embodiments from about 150 nm to about 2 microns. A person of ordinary skill in the art will recognize that additional ranges of release layer thickness within the explicit ranges above are contemplated and are within the present disclosure.

In some embodiments, two or more porous particular layers can be deposited. The different porous particulate release layers can differ in their morphology and/or with respect to composition. For example, it can be desirable to deposit a second porous, particulate layer have a smaller average primary particle size so that the layer forms a flatter denser surface for subsequent dense layer deposition. If the first porous, particulate layer has a lower density, it provides more facile fracture to provide the release function while the second layer provides for a gradual transition such that the dense over-layer(s) have more desirable properties and uniformity.

Furthermore, a second porous, particular layer can have a composition different from an underlying porous, particulate release layer to provide a lower melting, softening, and/or flow temperature relative to the first porous, particulate release layer. Thus, upon heating to an appropriate temperature, the second porous, particulate layer can further densify while the underlying porous, particulate release layer does not significantly densify. This densification of the porous, particulate over-layer can take place during the deposition of a dense over-layer if the deposition temperature is high enough, and/or during a post deposition heat treatment. For example, with a dense silicon layer, a post deposition zone melt recrystallization step can be performed to improve the properties of the silicon material. The second porous, particulate layer is intermediate relative to the porous particulate under-layer and the dense over-layer, and can densify during this zone melt recrystallization process. In general, the second porous particulate release layer can span the same range of compositions as the first porous, particulate release layer, although the particulate composition or dopant can be selected to yield the desired softening, melting and/or flow temperature.

Because the powder is mechanically compliant, the release layer can absorb differences of thermal expansion between the substrate and the subsequently deposited over layers to reduce thermal distortion, which can damage the substrate. This advantageous property of the release layer allows a wider variety of substrates and increases the re-use lifetime of the substrates. Also, the porous, particulate layer deposited as the release layer can be selected to be slightly or partially sinterable at high temperatures in order to provide additional mechanical stability while maintaining a high relative mechanical fragility to the release layer. A highly porous yet slightly sintered powder can maintain some rigidity and adhesion at high temperatures while fracturing appropriately. In some embodiments, fracturing can be facilitated during cooling of the resulting structure with the over-layer(s) as influenced by the accompanying thermal expansion mismatch between substrate and deposited over-layers.

The porous, particulate release layer formed can exhibit other special, desirable properties, such as unevenness or texture in its surface and a low thermal conductivity value. As for the texture of the surface of the soot layer, it may be imprinted on subsequently deposited layers. For photovoltaic applications, the texture on the subsequent layers can be used in solar cells to scatter light and enhance internal reflectance (i.e. light trapping). As for the low thermal conductivity value of the release layer, less thermal energy may be wasted by conduction to the substrate if subsequently deposited layers require heat treatment.

For the mechanical fracturing of the release layer, while the low mechanical strength of the release layer material can facilitate fracture of the release layer, generally it is desirable for the release layer to have a lower density than the surrounding materials. In particular, the release layer can have a porosity of at least about 40 percent, in some embodiments at least about 45 percent and in further embodiments from about 50 to about 90 percent porosity. A person of ordinary skill in the art will recognize that additional ranges of porosity within the explicit ranges above are contemplated and are within the present disclosure. Porosity is evaluated from a scanning electron microscopy (SEM) evaluation of a cross section of the structure in which the area of the pores is divided by the total area.

To achieve a lower density of the release layer, the release layer can be deposited with a lower density than surrounding materials. However, in some embodiments, the lower density of the release layer can result from reduced or eliminated densification of the release layer in post deposition processing while an over-layer and, optionally, an under-layer are more fully densified. This difference in densification can be the result of having a material with a higher flow temperature than surrounding undensified material and/or a larger primary particle size that results in a higher flow temperature. For these embodiments, the densification of the over-layer and, optionally, of an under-layer can result in a release layer with a lower density than the surrounding materials and with a correspondingly low mechanical strength. This lower mechanical strength can be exploited to fracture the release layer without damaging the over-layer.

Porous, particulate release layers can be formed using light reactive deposition. In particular, light reactive deposition can deposit powder coatings with an appropriate porosity for the use of the coating as a release layer. Furthermore, light reactive deposition has been used for the deposition of a wide range of compositions, such that an appropriate composition can be selected for the appropriate use as a release layer. The use of light reactive deposition for the formation of a porous, particulate release layer is described further in U.S. Pat. No. 6,788,866 to Bryan, entitled “Layer Materials and Planar Optical Devices,” and published U.S. patent application 2007/0212510A to Hieslmair et al., entitled “Thin Silicon or Germanium Sheets and Photovoltaics Formed From Thin Sheets,” both of which are incorporated herein by reference.

In additional embodiments, a porous, particulate release layer can be formed from a dispersion of submicron particles that are deposited onto a substrate to form the release layer as a particle coating on a substrate surface. The particles can be delivered with or without surface modification. In some embodiments, the particles can be well dispersed into a liquid for forming the release layer. Specifically, the volume average particle size can be no more than about 5 times the average primary particle size. In some embodiments, the average primary particle size is no more than about a micron, in further embodiments no more than about 100 nm and in additional embodiments form about 2 nm to about 75 nm. A person of ordinary skill in the art will recognize that additional ranges of average primary particle size within the explicit ranges above are contemplated and are within the present disclosure. Laser pyrolysis provides a suitable approach for the synthesis of suitable powders for dispersing into appropriate coating solutions. Laser pyrolysis is suitable for the synthesis of a large range of particle compositions as described further in published U.S. patent application 2006/0147369A to Bi et al., entitled “Nanoparticle Production and Corresponding Structures,” incorporated herein by reference.

If the particles are well dispersed with a suitable secondary particle size, the dispersion can be deposited into a resulting layer having an appropriate packing density, which is generally no more than about 60 percent, and in some embodiments at least about 10 percent of the density of the fully densified material. A person of ordinary skill in the art will recognize that additional ranges of packing density within the explicit ranges above are contemplated and are within the present disclosure. The powder coating can be evaluated for porosity essentially as described above to evaluate the nature of the release layer. The dispersion generally can be relatively concentrated with a particle concentration of at least about 0.5 weight percent. The well dispersed particles can be deposited onto a substrate using appropriate coating techniques. The deposited particle coating can be dried and, optionally pressed to form the release layer. The formation of good dispersion of submicron inorganic particles is described further in copending U.S. patent application Ser. No. 11/645,084 to Chiruvolu et al., entitled “Composites of Polymers and Metal/Metalloid Oxide Nanoparticles and Methods for Forming These Composites,” incorporated herein by reference. The formation of dispersion of silicon oxide submicron particles is described further in copending U.S. patent application Ser. No. 12/006,459, filed on Jan. 2, 2008 to Hieslmair et al., entitled “Silicon/Germanium Oxide Particle Inks, Inkjet Printing and Processes for Doping Semiconductor Substrates,” incorporated herein by reference.

The dispersions can be delivered using a range of delivery approaches, such as spray coating, dip coating, roller coating, spin coating, printing and the like. Spin coating can be a desirable approach for forming uniform layers of particulate dispersions. Spin coating apparatuses are described further in U.S. Pat. No. 5,591,264 to Sugimoto et al., entitled “Spin Coating Device,” incorporated herein by reference. For the formation of powder coatings on large substrates in an in-line format, spray coating can be a desirable approach. Spray coating processes are described further in U.S. Pat. No. 7,101,735 to Noma et al., entitled “Manufacturing Method of Semiconductor Device,” incorporated herein by reference. The concentrations of the dispersions can be selected to obtain desired degree of dispersion of the particles within the dispersing liquid for the particular coating approach. The dispersing liquid can be removed by evaporation following the deposition process.

For the formation of silicon foils on top of the release layer, the release layer can comprise silicon based ceramic compositions, such as silicon oxide, silicon nitride, silicon oxynitride, silicon carbide, silicon carbonitride and the like. To form these materials using light reactive deposition, gaseous silanes can be conveniently supplied in the reactant flow, and the reactant flow can comprise secondary reactants such as molecular oxygen (O₂), ammonia (NH₃), or hydrocarbons, such as ethylene (C₂H₄) to supply the non-silicon atoms. The reactant flow can also include inert diluent gases to moderate the reaction. Light reactive deposition is described further in published U.S. patent application 2003/0228415A, to Bi et al., entitled “Coating Formation by Reactive Deposition,” incorporated herein by reference.

The separation force to fracture a porous, particulate release layer can be applied by supplying mechanical energy. Mechanical energy can be supplied, for example, as ultrasonic vibrations, mechanical vibrations shear force and the like. Alternatively, the layers can be pulled apart. In addition, heat/cooling and/or pressure can be supplied to facilitate the separation based on difference in the coefficient of thermal expansion. Cooling can be accomplished, for example, by contacting the structure with liquid nitrogen.

In some embodiments, the release layer can be chemically separated from surrounding layers. For example, the release layer can be soluble in a solvent that does not dissolve the overcoat layer. To etch SiO₂ without reacting with silicon, hydrofluoric acid can be used.

To facilitate the separation of the overcoat from the release layer and substrate, the overcoat material can be releasably adhered to a transfer surface. The transfer surface can be approximately equal in size, larger than or smaller than the surface of the overcoat to be released. The association with a transfer surface can be made, for example, with an adhesive, suction, static electricity or the like. The transfer surface can be used to apply shear and/or pulling motion to the overcoat to deliver mechanical energy to rupture the release layer. In some embodiments, an overcoat structure can be associated with a transfer surface to facilitate certain processing of the thin separated structure. For appropriate embodiments, the adhesive can be chemically or physically removed to release the thin separated structure from the transfer surface associated with a temporary substrate. In some embodiments, the transfer surface can be associated with a permanent substrate that is attached to the overcoat for formation into a product. Also, the thin structure can be transferred between substrates using comparable approaches after release from the release layer. The handling and transfer between substrates of an inorganic foil is described further in copending U.S. provisional patent application Ser. No. 61/062,399 to Mosso et al., entitled “Layer Transfer for Large Area Inorganic Foils,” incorporated herein by reference.

The resulting inorganic foil may have a portion of the fractured release layer attached. If desired, remnants of the release layer associated with the inorganic foil can be removed from the release thin structure using appropriate methods, such as etching or polishing. Depending on the nature of the release layer material, residual release layer material can be removed with mechanical polishing and/or chemical-mechanical polishing. Mechanical polishing can be performed with motorized polishing equipment, such as equipment known in the semiconductor art. Similarly, any suitable etching approach, such as chemical etching and/or radiation etching, can be used to remove the residual release layer material. Also, substrates can be similarly cleaned to remove residual release layer material using chemical cleaning and/or mechanical polishing. Thus, a high quality substrate structure can be reused multiple times while taking advantage of the high quality of the substrate.

### Over-Layers and Inorganic Foils

In general, one or more over-layers can be deposited on a porous, particulate release layer. Fracturing or otherwise releasing the over-layers at the release layer can result in an inorganic foil. Appropriate portions of the discussion below also apply to coating layers deposited using scanning sub-atmospheric pressure CVD that are applied as permanent layers without association with a release layer. In general, the over-layers can comprise a selected composition, and the over-layers can have selected properties based on the intended use of the resulting structure. In some embodiments, at least one of the over-layers is an elemental silicon layer, which may or may not be doped. The elemental silicon layer can be subsequently applied in various semiconductor applications. With the ability to separate an overcoat structure from the underlying substrate, the large area and thin elemental silicon and/or germanium foils can be formed as well as other structures. The separated structures can be processed into desired devices, such as photovoltaic devices or displays. If a plurality of over-layers is deposited on the release layer, additional processing of the layers, such as a heat treatment, can be performed between deposition steps and/or after the deposition of the plurality of layers is completed.

The performance of directed-flow reactive deposition approaches described herein can be used to produce coatings with a selected composition from a broad range of available compositions. Specifically, the compositions generally can comprise one or more metal/metalloid, i.e. metal and/or metalloid, elements forming a crystalline, partially crystalline or amorphous material. In addition, dopant(s) can be used to alter the chemical and/or physical properties of the coating. Incorporation of the dopant(s) into the reactant flow can result in an approximately uniform distribution of the dopant(s) through the coating material.

In general, coating materials can comprise, for example, elemental metal/metalloid, and metal/metalloid compositions, such as, metal/metalloid oxides, metal/metalloid carbides, metal/metalloid nitrides, metal/metalloid phosphides, metal/metalloid sulfides, metal/metalloid tellurides, metal/metalloid selenides, metal/metalloid arsinides, mixtures thereof, alloys thereof and combinations thereof. Alternatively or additionally, such coating compositions can be characterized as having the following formula:

AₐB_{b}C_{c}D_{d}EₑF_{f}G_{g}HₕIᵢJⱼKₖLₗMₘNₙOₒ,

where each A, B, C, D, E, F, G, H, I, J, K, L, M, N, and O is independently present or absent and at least one of A, B, C, D, E, F, G, H, I, J, K, L, M, N, and O is present and is independently selected from the group consisting of elements of the periodic table of elements comprising Group 1A elements, Group 2A elements, Group 3B elements (including the lanthanide family of elements and the actinide family of elements), Group 4B elements, Group 5B elements, Group 6B elements, Group 7B elements, Group 8B elements, Group 1B elements, Group 2B elements, Group 3A elements, Group 4A elements, Group 5A elements, Group 6A elements, and Group 7A elements; and each a, b, c, d, e, f, g, h, i, j, k, l, m, n, and o is independently selected and stoichiometrically feasible from a value in the range(s) from about 1 to about 1,000,000, with numbers of about 1, 10, 100, 1000, 10000, 100000, 1000000, and suitable sums thereof being contemplated. The materials can be crystalline, amorphous or combinations thereof. In other words, the elements can be any element from the periodic table other than the noble gases. As described herein, in suitable contexts all inorganic compositions are contemplated, as well as all subsets of inorganic compounds as distinct inventive groupings, such as all inorganic compounds or combinations thereof except for any particular composition, group of compositions, genus, subgenus, alone or together and the like.

In some embodiments, it is desirable to incorporate one or more dopants into a silicon/germanium-based semiconductor material, for example, to form n-type semiconductors or p-type semiconductors. Suitable dopants to form n-type semiconductors contribute extra electrons, such as phosphorous (P), arsenic (As), antimony (Sb) or mixtures thereof. Similarly, suitable dopants to form p-type semiconductors contribute holes, i.e., electron vacancies, such as boron (B), aluminum (Al), gallium (Ga), indium (In) or combinations thereof.

For CVD deposition, suitable precursors for Si include, for example, silane (SiH₄) and disilane (Si₂H₆). Suitable Ge precursors include, for example, germane (GeH₄). Suitable boron precursors include, for example, BH₃ and B₂H₆. Suitable P precursors include, for example, phosphine (PH₃). Suitable Al precursors include, for example, AlH₃ and Al₂H₆. Suitable Sb precursors include, for example, SbH₃. Suitable precursors for vapor delivery of gallium include, for example, GaH₃. Arsenic precursors include, for example, AsH₃.

For material synthesis in a reactive flow, suitable oxygen sources include, for example, O₂, N₂O or combinations thereof, and suitable nitrogen sources include, for example, ammonia (NH₃), N₂ and combinations thereof. The range of compositions available with light reactive deposition is described further in copending U.S. patent application Ser. No. 11/017,214 to Chiruvolu et al., entitled “Dense Coating Formation by Reactive Deposition,” incorporated herein by reference.

Dopant concentrations can be selected to yield desired properties. In some embodiments, the average dopant concentrations can be at least about 1×10¹³ atoms per cubic centimeter (cm³), in further embodiments, at least about 1×10¹⁴ atoms/cm³, in other embodiments at least about 1×10¹⁶ atoms/cm³ and in further embodiments 1×10¹⁷ to about 5×10²¹ atoms/cm³. With respect to atomic parts per million (ppma), the dopant can be at least about 0.0001 ppma, in further embodiments at least about 0.01 ppma, in additional embodiments at least about 0.1 ppma and in other embodiments from about 2 ppma to about 1×10⁵ ppma. A person of ordinary skill in the art will recognize that additional ranges of dopant concentrations within the explicit ranges above are contemplated and are within the present disclosure. While certain people of ordinary skill in the art use n+, n++, p+and p++ to designate certain dopant concentration ranges for n-type and p-type dopants, this notation is not used herein to avoid possible ambiguities or inconsistencies.

In general, the dopant concentrations may or may not be uniformly distributed through a layer of material. In some embodiments, there is a gradient in dopant concentration. A gradient can be step-wise, which can be formed through multiple scans through the deposition chamber or through sequential scans through multiple deposition chambers in which the dopant concentration is adjusted between scans. Such a gradient can be selected to yield desired properties in the resulting product. Specifically, gradients near surfaces and interfaces can be useful for reducing electrical loses at surfaces and interfaces.

Suitable dielectric materials for appropriate applications include, for example, metal/metalloid oxides, metal/metalloid carbides, metal/metalloid nitrides, combinations thereof, or mixtures thereof If the dielectric is adjacent a semiconductor layer comprising silicon and/or germanium, it can be convenient to use a corresponding silicon/germanium composition for the dielectric. Thus, for a silicon-based photovoltaic, it may be desirable to incorporate a silicon oxide, a silicon nitride, a silicon oxynitride and/or a silicon carbide as a dielectric adjacent the silicon-based semiconductor. However, it has been found that a thin layer of aluminum oxide on the front surface of a solar cell can improve cell efficiency. (Presentation by researchers from the Eindhoven University of Technology and Fraunhofer Institute at the 33rd IEEE Photovoltaic Specialists Conference, San Diego, Calif., USA, May 11-16, 2008.) Aluminum oxide layers can be deposited efficiently in a scanning mode using light reactive deposition, scanning sub-atmospheric pressure CVD or atmospheric pressure CVD.

To obtain particular objectives, the features of a coating can be varied with respect to composition of layers of the coating as well as location of materials on the substrate. Generally, to form a device the coating material can be localized to a particular location on the substrate. In addition, multiple layers of coating material can be deposited in a controlled fashion to form layers with different compositions. Similarly, the coating can be made a uniform thickness, or different portions of the substrate can be coated with different thicknesses of coating material. Different coating thicknesses can be applied such as by varying the sweep speed of the substrate relative to the particle nozzle, by making multiple sweeps of portions of the substrate that receive a thicker coating or by patterning the layer, for example, with a mask. Alternatively or additionally, a layer can be contoured by etching or the like following deposition.

Thus, layers of materials, as described herein, may comprise particular layers that do not have the same planar extent as other layers. For example, some layers may cover the entire substrate surface or a large fraction thereof while other layers cover a smaller fraction of the substrate surface. In this way, the layers can form one or more localized devices. At any particular point along the planar substrate, a sectional view through the structures may reveal a different number of identifiable layers than at another point along the surface.

The directed flow reactive deposition approaches described herein can be effective for forming high quality coatings for applications in which an appropriate coating thickness is generally moderate or small, and very thin coatings can be formed as appropriate. Thickness is measured perpendicular to the projection plane in which the structure has a maximum surface area, which is generally perpendicular to a planar surface of an underlying substrate. For some applications, the coatings have a thickness in the range(s) of no more than about 2000 microns, in other embodiments, in the range(s) of no more than about 500 microns, in additional embodiments in the range(s) from about 5 nanometers to about 100 microns and in further embodiments in the range(s) from about 100 nanometers to about 50 microns. A person of ordinary skill in the art will recognize that additional range(s) within these explicit ranges and subranges are contemplated and are encompassed within the present disclosure.

Due to the relatively high deposition rate combined with the high coating uniformity with deposition approaches herein, large substrates can be effectively coated. With larger widths of the substrate, the substrate can be coated with one or multiple passes of the substrate through the product stream. Specifically, a single pass can be used if the substrate is roughly no wider than the inlet nozzle of the reactor such that the product stream is approximately as wide as or somewhat wider than the substrate. With multiple passes, the substrate is moved relative to the nozzle with the length of an elongated opening from the nozzle in a direction oriented along the width of the substrate. Thus, it is straightforward to coat substrates in some embodiments with a width of at least about 20 centimeters, in other embodiments at least about 25 cm, in additional embodiments from about 30 cm to about 2 meters, in further embodiments no more than about 1.5 meters and in some embodiments no more than 1 meters. A person of ordinary skill in the art will recognize that additional ranges of widths within these explicit ranges are contemplated and are within the present disclosure.

In general, for convenience, the length is distinguished from the width of a substrate in that during the coating process, the substrate is generally moved relative to its length and not relative to its width. With this general principle in mind, the distinction may or may not be particularly relevant for a particular substrate. The length is generally only limited by the ability to support the substrate for coating. Thus, lengths can be at least as large as about 10 meters, in some embodiments from about 10 cm to about 5 meters, in further embodiments from about 30 cm to about 4 meters and in additional embodiments from about 40 nm to about 2 meters. A person of ordinary skill in the art will recognize that additional ranges of substrate lengths within these explicit ranges are contemplated and are within the present disclosure.

As a result of being able to coat substrates with large widths and lengths, the coated substrates can have very large surface areas. In particular, substrates sheets can have surface areas of at least about 900 square centimeters (cm²), in further embodiments, at least about 1000 cm², in additional embodiments from about 1000 cm² to about 10 square meters (m²) and in other embodiments from about 2500 cm² to about 5 m². With the ability to form thin structures through the use of a release layer, the large surface areas can be combined with particularly thin structures. In some embodiments, the large surface area inorganic foils can have a thickness of no more than about a millimeter, in other embodiments no more than about 250 microns, in additional embodiments no more than about 100 microns and in further embodiments from about 5 microns to about 50 microns. A person of ordinary skill in the art will recognize that additional ranges of surface area and thickness within the explicit ranges above are contemplated and are within the present disclosure.

While these thin, large area inorganic foils can be formed with a range of materials that can be produced with directed flow reactive deposition approaches, in some embodiments there is particular interest in thin silicon/germanium-based semiconductor materials with or without dopants. Specifically, in some embodiments of large area, thin silicon-based semiconductor foils, the sheets can have an average thickness of no more than about 100 microns. The large area and small thickness can be exploited in unique ways in the formation of improved devices while saving on material cost and consumption. Furthermore, in some embodiments, the thin silicon semiconductor films can have a thickness of at least about 2 microns, in some embodiments from about 3 microns to about 100 microns, and in other embodiments the silicon films have a thickness from about 5 microns to about 50 microns. A person of ordinary skill in the art will recognize that additional ranges of area and thickness within the explicit ranges above are contemplated and are within the present disclosure.

For embodiments involving a release layer, processes for the formation of a release layer are described in detail above. Also, the deposition over a porous, particulate layer provides for strain relief as well as for separation of the resulting layer, such as a polycrystalline silicon layer, such that the original substrate can be reused, and the separated foil can be processed into desired structures free from the original substrate. The overcoat structure can be formed with one or more of the directed-flow reactive deposition processes as discussed above. The formation of an overcoat over a release layer using Light Reactive Deposition is described in published U.S. patent application 2007/0212510 to Hieslmair et al., entitled “Thin Silicon or Germanium Sheets and Photovoltaics Formed From Thin Sheets,” incorporated herein by reference. The deposition using scanning sub-atmospheric pressure CVD is also discussed in detail above.

Directed-flow atmospheric pressure or scanning sub-atmospheric pressure CVD depositions can be performed to deposit over-layers in a light reactive deposition chamber at the selected pressure. Since thermal input from the chamber environment at less than atmospheric pressure may limit deposition rates, the apparatus can be configured to heat the substrate or the surface of the substrate to high temperatures to drive the reaction of the input precursor gas at the substrate surface at a high rate. A nozzle inlet with an elongated dimension of the inlet orifice oriented parallel to the width of the substrate can provide for the deposition along an entire substrate with one pass of the substrate with a sheet of reactants being directed at the substrate. The substrate can be mounted on a linearly translating stage or an alternative conveyor system. A polycrystalline silicon or other over-layer composition can be deposited at a relatively high thickness of several tens of microns in a single pass.

For appropriate directed-flow embodiments at sub-atmospheric pressures, a CVD deposition process can be termed scanning sub-atmospheric pressure chemical vapor deposition (SSAP-CVD). In some embodiments, the porous, particulate release layer can be deposited with light reactive deposition followed by the deposition of a silicon layer and optionally additional layers using SSAP-CVD within the same reactor, in which the laser is turned off prior to performing the SSAP-CVD deposition step. In some embodiments, the SSAP-CVD process can have greater control over the thermal processes of the deposition so that in principle a more uniform layer can be formed relative to APCVD. However, other forms of CVD generally can also take advantage of deposition on a porous layer to facilitate separation of the resulting layer as well as reducing strain. Although SSAP-CVD offers certain advantages, CVD can be performed in a light reactive deposition chamber at other pressures, such as at atmospheric pressure or higher than atmospheric pressure. Thus, for certain applications the SSAP-CVD process can offer certain advantages over other CVD processes with respect to the maintenance of a high deposition rate while within a light reactive deposition chamber, and in some embodiments prior and/or subsequent layers can be deposited with the versatile composition range available through either light reactive deposition process or the SSAP-CVD process.

The over-layers can be subjected to further processing following deposition prior to separation of the inorganic foil or prior to further device formation. For example, heat treatment can be used to densify and or anneal coatings. To densify the coating materials, the materials can be heated to a temperature above the melting point for crystalline materials or the flow temperature for amorphous materials, e.g., above the glass transition temperature and possibly above the softening point below which a glass is self-supporting, to consolidate the coating into a densified material by forming a viscous liquid. Sintering of particles can be used to form amorphous, crystalline or polycrystalline phases in layers. The sintering of crystalline particles can involve, for example, one or more known sintering mechanisms, such as surface diffusion, lattice diffusion, vapor transportation, grain boundary diffusion, and/or liquid phase diffusion. The sintering of amorphous particles generally can lead to the formation of an amorphous film. With respect to release layers, a partially densified material can be a material in which a pore network remains but the pore size has been reduced and the solid matrix strengthened through the fusing of particles to form rigid inter-particle necks.

Heat treatments for coated substrates can be performed in a suitable oven. It may be desirable to control the atmosphere in the oven with respect to pressure and/or the composition of the surrounding gases. Suitable ovens can comprise, for example, an induction furnace, a box furnace or a tube furnace with gas(es) flowing through the space containing the coated substrate. The heat treatment can be performed following removal of the coated substrates from the coating reactor. In alternative embodiments, the heat treatment is integrated into the coating process such that the processing steps can be performed sequentially in the apparatus in an automated fashion. Suitable processing temperatures and times generally depend on the composition and microstructure of the coatings. Zone melt recrystallization for improving the properties of semiconductor layers is described further below.

Photovoltaic Devices with Silicon Foils

The deposition approaches herein can be used to form inorganic foils and layered structures generally with a range of selected compositions. However, the formation of semiconductor structures can be particularly desirable. The following discussion focuses on elemental silicon semiconductor materials, although in this discussion germanium, silicon-germanium alloys and doped compositions thereof can be equivalently used. Thus, in the discussion of silicon semiconductor materials that follows, germanium, silicon-germanium alloys and doped compositions thereof can be substituted for silicon. As noted above, semiconductor foils can be used to form circuits, such as for the production of display circuits. However, the formation of photovoltaic devices is the focus of the following discussion. In some embodiments, the semiconductor material can be deposited onto a permanent substrate for further processing into a final device. However, in other embodiments, the semiconductor layer is deposited onto a release layer for the separation of a silicon foil that is processed into a photovoltaic device. One or a plurality of layers can be deposited onto the release layer prior to separating the semiconductor foil from the release layer.

In general, many different types of layers can be deposited on a release layer depending on the purposes of layers. In general, it can be convenient to deposit a plurality of layers onto the release layer for incorporation into a foil. The multiple layers can be processed further before and/or after separation from the substrate through fracturing of the release layer. With respect to the formation of semiconductor foils for photovoltaic cells, the semiconductor layer generally has a dielectric layer on both surfaces of the semiconductor layer, which can be formed before or after separation of the foil. The semiconductor layers are generally doped at relatively low levels to increase charge mobilities, although dopant levels are generally less than the dopant levels in doped contacts interfacing with the semiconductor layer to harvest the photocurrent.

In some embodiments, it is desirable to perform zone melt recrystallization of the silicon layer to increase the crystal size relative to the initial polycrystalline or amorphous silicon and to improve correspondingly the electrical properties of the semiconductor. In zone melt recrystalization, generally the coated substrate is translated past a strip heater that melts the silicon along a stripe. For example, a focused halogen lamp can be used as the linear heat source. A heater can be placed below the structure to control the base temperature of the structure. The melted material crystallizes as it cools after translating away form the heating zone. The crystals grow along a crystallization front. The speed of movement of the heater is controlled to adjust the distance between the melting front and the solidification front. There is a balance between a faster sweep speed that reduced processing costs with a slower sweep speed to get larger crystal grains and fewer crystal defects.

The objective is to increase the crystal size of the polycrystalline silicon upon completion of the recrystallization. When the silicon is melted, the surface of the material may not remain flat. Therefore, it can be desirable to have a capping layer of a high melting ceramic over the silicon layer that constrains the liquid silicon after it is melted. The zone melt recrystallization process can be advantageously adapted for embodiments which account for the thermal insulation of the release layer. The performance of zone melt recrystallization of a silicon film on a release layer is described further in copending U.S. patent application Ser. No. 12/152,907 filed on May 16, 2008 to Hieslmair et al, entitled “Zone Melt Recrystallization for Inorganic Films,” incorporated herein by reference. Specifically, in the case of a high temperature recrystallization step of a subsequently deposited silicon layer, the insulating release layer blocks thermal conduction from the silicon layer into the substrate, thus reducing wasted energy.

Various structures can be created by selectively depositing layers with light reactive deposition steps and CVD deposition steps. Specifically, several layers with various functions can be deposited to create more complex structures. In general, it can be desirable to deposit a porous, particulate release layer over the surface of a reusable substrate. The substrate can be a high melting ceramic material, such as silicon carbide. As noted above, it can be desirable to have a capping layer over the silicon layer. One or more layers can be placed optionally between the silicon layer and the release layer. Specifically, in some embodiments, it can be desirable to deposit one or more ceramic layers with a high melting point between the porous, particulate release layer and the silicon layer. Suitable ceramic materials for incorporation into the structure include, for example, silicon oxide, silicon nitride, silicon oxynitride, silicon carbide, silicon carbonitride, silicon rich variants thereof, combinations thereof and mixtures thereof. In some embodiments, silicon nitride can be desirable as an under layer since it wets liquid silicon.

As noted above, the release layer can be advantageously deposited using light reactive deposition. Dense layers can be deposited on top of the release layer using scanning sub-atmospheric pressure CVD as well as light reactive deposition adapted for denser layer deposition and/or other forms of CVD. Once the deposition processes are completed, the resulting structure can be transferred to a chamber for the performance of zone melt recrystallization while the structure is still hot so that this heat can reduce the amount of heat that is added during the zone melt recrystallization process.

Subsequent to the recrystallization process, for embodiments based on a release layer, it is generally desirable to separate the recrystallized film from the substrate. The substrate can then be appropriately cleaned and/or polished for reuse. Some approaches for handling the released inorganic foil and for performing the separation process are described further in copending provisional patent application Ser. No. 61/062,399, filed Jan. 25, 2008 to Mosso et al., entitled “Layer Transfer for Large Area Inorganic Foils,” incorporated herein by reference.

To form a photovoltaic module based on a semiconductor foil, a selected additional layer(s) can function as a passivation layer on the front surface, rear surface or both. A passivation layer can also function as an antireflective layer. In some embodiments, suitable ceramic materials described above can be incorporated into a solar cell as a passivation layer. The solar cell can have the silicon layer that functions as a bulk semiconductor and doped domains that form portions of contacts associated with current collectors. Specifically, photovoltaic cells based on silicon, germanium or alloys thereof incorporate a junction with respective contacts comprising respectively a p-type semiconductor and an n-type semiconductor. The flow of current between current collectors of opposite polarity can be used useful work. The doped contacts can be formed following separation of the foil from the release layer or before such separation. The silicon foil structure can be effectively processed into a solar cell with both p-doped and n-doped contacts along the rear surface of the cell.

The processes described herein are suitable for the formation of desirable materials for photovoltaic cells. The use of thinner semiconductor structures results in a saving with respect to materials and corresponding costs. However, if the semiconductor is too thin, the silicon does not capture as much light. Thus, there are advantages in having a polycrystalline silicon/germanium-based semiconductor thickness of at least two microns and no more than 100 microns. The processing of thin film silicon foils into solar cells with rear doped contacts is described in detail in copending U.S. patent application Ser. No. 12/070,371 to Hieslmair et al., entitled “Solar Cell Structures, Photovoltaic Panels, and Corresponding Processes,” and in copending U.S. patent application Ser. No. 12/070,381 to Hieslmair, entitled “Dynamic Design of Solar Cell Structures, Photovoltaic Panels and Corresponding Processes,” both of which are incorporated herein by reference. Specifically, these copending patent applications further describe the formation of photovoltaics from thin silicon sheets separated from an underlying porous release layer, and these approaches can be adapted for the thin silicon sheets formed by the methods described herein. One or more of the device processing steps can be incorporated into an in-line procedure downstream from the ZMR apparatus, and the in-line procedure can produce final photovoltaic panels in some embodiments.

### EXAMPLES

### Example 1

### Scanning Sub-Atmospheric Pressure CVD onto a Release Layer

This example demonstrates the ability to deposit a high quality silicon foil layer using scanning sub-atmospheric pressure CVD onto a release layer formed using light reactive deposition.

The depositions were performed in a reactor essentially as described in published U.S. patent application 2007/0212510, filed Mar. 13, 2007 to Hieslmair et al., entitled “Thin Silicon or Germanium Sheets and Photovoltaics Formed From Thin Sheets,” incorporated herein by references. The CVD deposition was performed with the laser turned off using the same reactant supply system with appropriately selected reactants delivered for the particular deposition process.

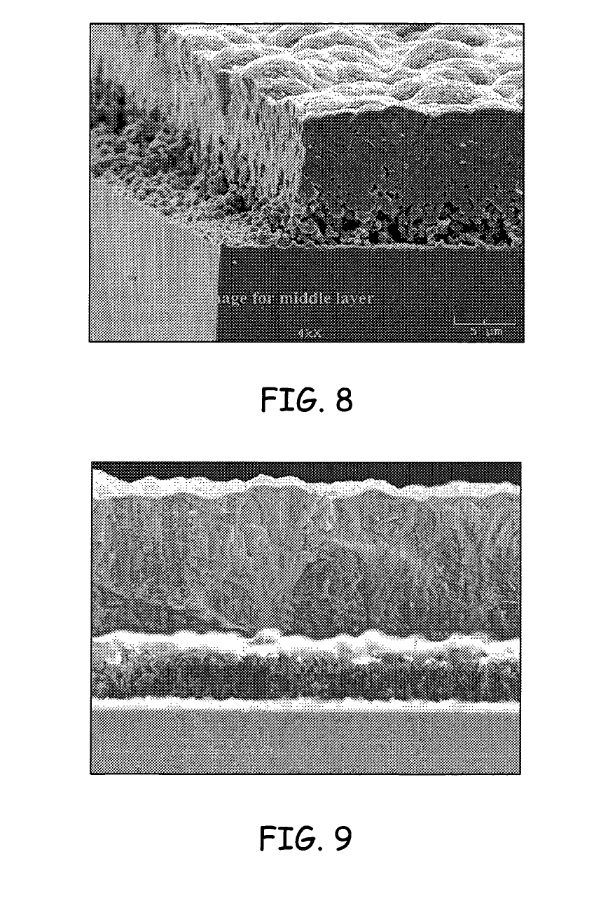

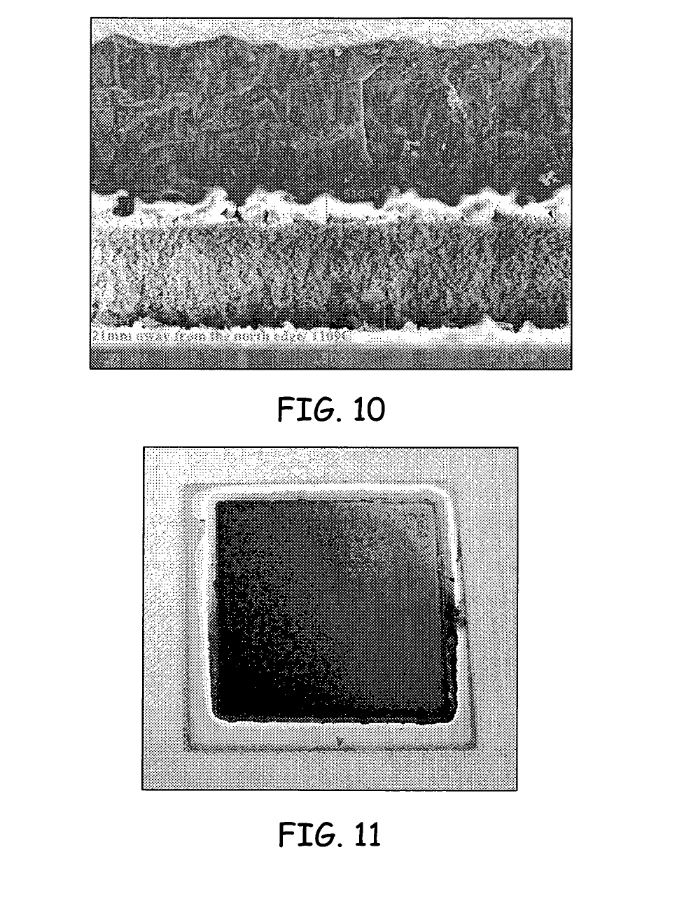

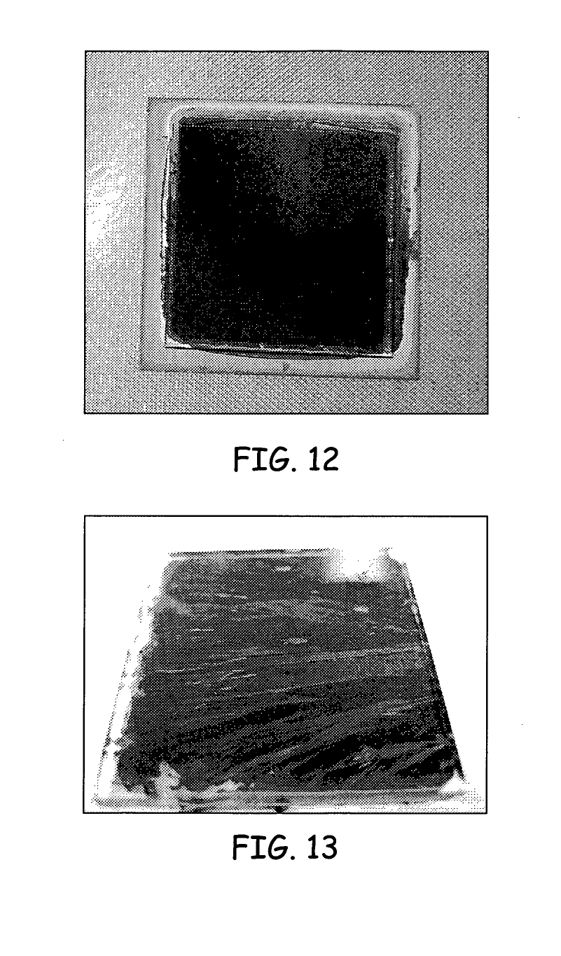

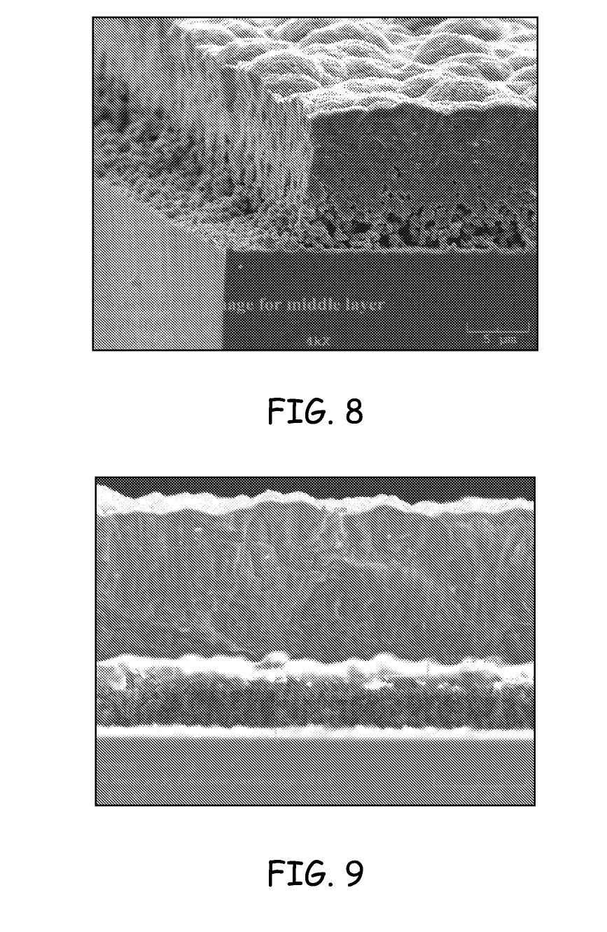

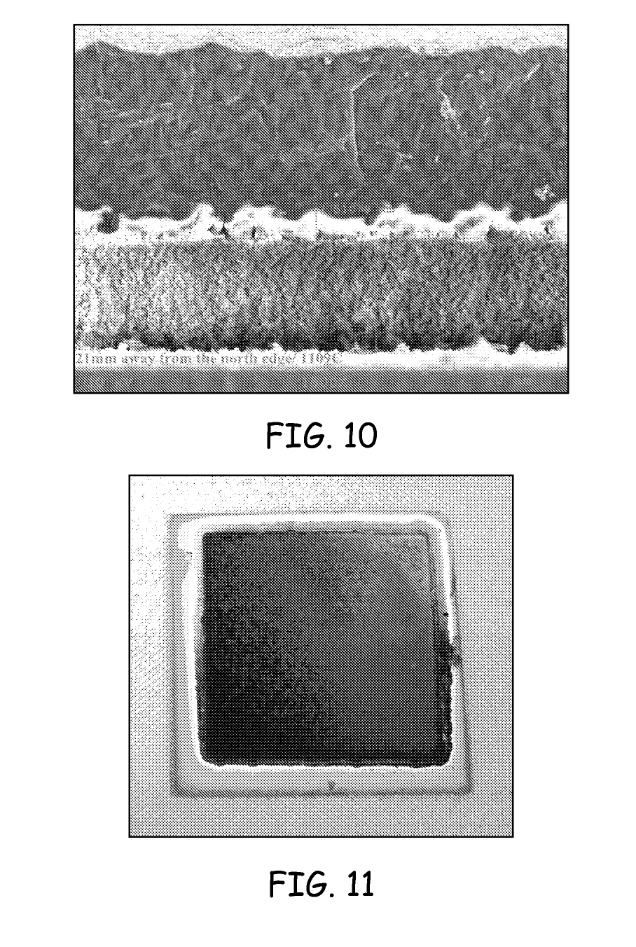

A stack of deposited layers is shown in the FIG. 8. Starting from the bottom of the micrograph, the layers can be identified as follows: substrate, micron porous silicon nitride layer formed with light reactive deposition and a dense CVD silicon film. Two other representative embodiments are shown in FIGS. 10 and 11. Referring to FIG. 10, the layers from the bottom up are as follows: substrate, 10.6 micron porous silicon nitride layer formed by light reactive deposition, 8.3 micron silicon nitride CVD layer, 31.4 micron CVD silicon layer, and a 770 nm silicon nitride CVD layer. Referring to FIG. 11, the layers from the bottom up are as follows: substrate, 21.2 micron porous silicon nitride layer formed by light reactive deposition, 7.5 micron silicon nitride CVD layer, 28.7 micron CVD silicon layer and 930 nm silicon nitride CVD layer.

Several CVD silicon films have been synthesized on porous silicon nitride soot layers using the apparatus of this example. We have obtained silicon film thicknesses from 5 to 35 microns or more. We observe that the deposited silicon nearest the porous/release layer, inherits a porous morphology from the release layer. Gradually, as the silicon CVD film grows, the morphology becomes more crystalline and dense.

### Example 2

### Separation of Silicon Foil at the Release Layer

This example demonstrates the ability to separate a silicon foil through the fracture of a porous particulate release layer.

A series of depositions was performed to form a structure essentially as described above with respect to FIG. 9. In general, samples have been formed generally at about 600 Torr or lower pressures with layers generally within the ranges of 10 to 40 microns of porous particulate silicon nitride formed by light reactive deposition, 5 to 10 microns of SSAP-CVD silicon nitride, about 35 microns of SSAP-CVD silicon and a thin silicon nitride capping layer. After deposition, the silicon was subjected to a zone melt recrystallization process. In the ZMR process, the structure was scanned past a radiant heater to melt the silicon, which subsequently recrystallizes as the material cools. A photograph of the resulting structure is shown in FIG. 11.

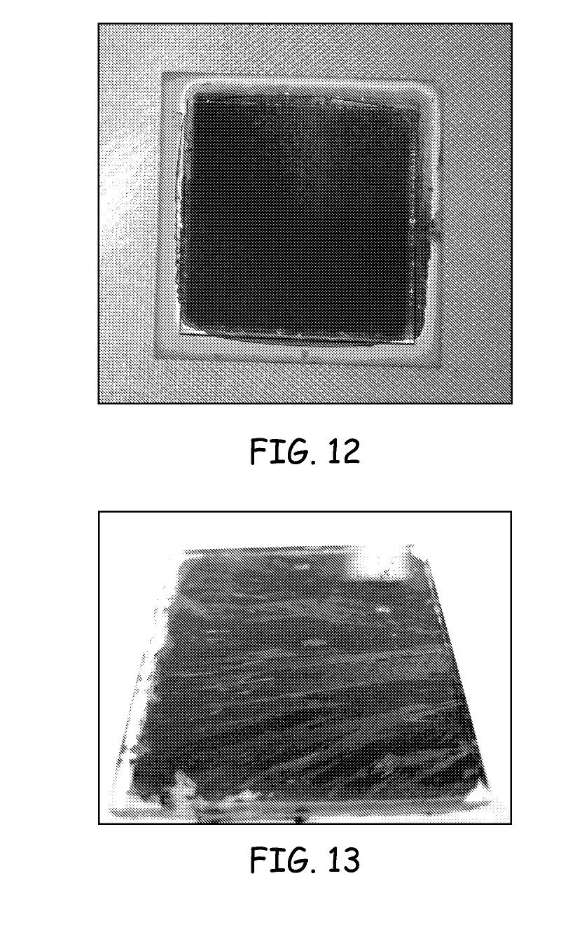

To perform the separation, a crosslinking ethylenevinylacetate (EVA) polymer adhesive was applied to the surface of a sheet of glass. The adhesive coated surface was placed onto of the coated substrate. A laminator was then used to apply heat and pressure to the glass plate on top of the substrate to laminate the glass plate to the film stack. A photograph of the laminated structure is shown in FIG. 12.

The glass piece with the adhered silicon foil was separated from the substrate by hand using a slight mechanical force. A representative picture of the glass plate with the separated silicon foil is shown in FIG. 13. The foil was substantially intact following separation. The separation process was reproducible.

The embodiments above are intended to be illustrative and not limiting. Additional embodiments are within the claims. In addition, although the present invention has been described with reference to particular embodiments, those skilled in the art will recognize that changes can be made in form and detail without departing from the spirit and scope of the invention. Any incorporation by reference of documents above is limited such that no subject matter is incorporated that is contrary to the explicit disclosure herein.

What is claimed is:

1. A method for forming an inorganic layer on a release layer supported on a substrate, the method comprising:
depositing an inorganic layer onto a porous, particulate release layer using chemical vapor deposition.

2. The method of claim 1 wherein the depositing step is performed in a reaction chamber at a pressure from about 50 Torr to about 650 Torr and at a pressure below ambient pressure.

3. The method of claim 1 wherein the reactants for the chemical vapor deposition process flow from an inlet of a nozzle oriented to direct flow from the inlet to the release layer.

4. The method of claim 1 wherein the chemical vapor deposition reaction comprises a thermal decomposition reaction.

5. The method of claim 4 wherein the inorganic layer comprises elemental silicon.

6. The method of claim 1 wherein the release layer comprises a fused network of submicron particles.

7. The method of claim 1 wherein the release layer is formed through the deposition of a dispersion of particles.

8. The method of claim 1 wherein the substrate is heated to facilitate the chemical vapor deposition.

9. The method of claim 1 wherein the chemical vapor deposition is enhanced using a plasma, a heated filament or an electron beam.

10. The method of claim 1 wherein a porous, particulate under-layer is positioned under the porous, particulate layer, wherein the porous, particulate under-layer has a larger primary particle size relative to the porous, particulate layer.

11. A method for depositing an inorganic layer, the method comprising:
depositing an inorganic material using chemical vapor deposition onto a substrate that is moving relative to a flow of reactants delivered from a nozzle inlet in a reaction chamber with a pressure from about 50 Torr to about 700 Torr and at a pressure below ambient pressure.

12. The method of claim 11 wherein the nozzle is fixed with respect to the reaction chamber and the substrate moves relative to the reaction chamber.

13. The method of claim 11 wherein the substrate is heated to facilitate a thermal reaction to form a product composition at the substrate.

14. The method of claim 11 wherein the inorganic material comprises elemental silicon and wherein the reactants undergo a thermal decomposition reaction.

15. The method of claim 11 wherein an exhaust conduit from the reaction chamber is positioned adjacent the nozzle inlet.

16. The method of claim 11 wherein the pressure is from about 75 Torr to about 600 Torr.

17. A layered structure comprising a substrate, a powder layer on the substrate and an approximately dense silicon layer deposited onto the powder layer wherein the silicon layer has a thickness from about 2 microns to about 100 microns.

18. The layered structure of claim 17 wherein the layer has a thickness from about 10 microns to about 60 microns.

19. The layered structure of claim 17 wherein the powder layer comprises silicon nitride, silicon oxide, silicon oxynitride or combinations thereof.

20. The layered structure of claim 17 wherein the powder layer has a thickness form about 50 nm to about 50 microns.

21. The layered structure of claim 17 wherein the layer has a surface area or at least about 100 square centimeters.

22. A method for forming an inorganic layer on a release layer, the method comprising:
forming a power coating on a substrate wherein the formation of the coating comprises depositing a particle dispersion onto a substrate; and
depositing an inorganic composition onto the powder coating from a reactive flow in which the reactive flow is initiated from an inlet of nozzle directed at the substrate.

23. The method of claim 22 wherein the dispersion comprises particles having a volume average secondary particle size of no more than about 2 microns and a particle concentration of at least about 2 weight percent.

24. The method of claim 22 wherein the depositing of the particle dispersion comprises spin coating the dispersion.

25. The method of claim 22 wherein the particle dispersion comprises particles that are surface modified with a chemically bonded organic composition.

26. The method of claim 22 where the reactant flow passes through a light beam to drive a reaction to form a product flow that is directed to the substrate.

27. The method of claim 22 wherein the depositing of the inorganic compositions comprises chemical vapor deposition.
